(19) United States
(12) Patent Application Publication
(10) Pub. No.: US 2026/0068221 A1
(43) Pub. Date: Mar. 5, 2026

(54) SEMICONDUCTOR STRUCTURE AND METHOD FOR FORMING THE SAME

(71) Applicant: Taiwan Semiconductor Manufacturing Company, Ltd., Hsinchu (TW)

(72) Inventors: Jiun-Jie CHAO, Miaoli County (TW); Yu-Ho CHIANG, Hsinchu (TW); Wen-Chiang HONG, Taipei City (TW); Ting-Gang CHEN, Taipei City (TW); Yuan-Sheng HUANG, Taichung City (TW); Jyh-Huei CHEN, Hsinchu City (TW); Jye-Yen CHENG, Taichung (TW)

(73) Assignee: Taiwan Semiconductor Manufacturing Company, Ltd., Hsinchu (TW)

(21) Appl. No.: 18/818,003

(22) Filed: Aug. 28, 2024

(51) Int. Cl. H01L 29/417; H01L 21/285; H01L 29/06; H01L 29/423; H01L 29/66; H01L 29/775; H01L 29/786

(52) U.S. Cl. CPC H10D 30/6729; H10D 30/014; H10D 30/43; H10D 30/6735; H10D 30/6757; H10D 62/121; H10D 64/017; H10D 64/018

(57) ABSTRACT

A method of forming a semiconductor structure includes forming a fin structure; forming first and second source/drain trenches in the fin structure; forming first and second semiconductor material layers in the first and second source/drain trenches, respectively; and forming first and second source/drain features over the first and second semiconductor material layers in the first and second source/drain trenches, respectively. The method further includes flipping the semiconductor structure; forming a hard mask layer on a backside of the substrate; etching the hard mask layer and the substrate to form a first opening that exposes the first semiconductor material layer; forming an insulating layer on a sidewall of the first opening; removing the first semiconductor material layer to form a second opening that exposes the first source/drain feature; and depositing a conductive material in the first and second openings to form a first source/drain contact.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometric size (i.e., the smallest component (or line) that can be created using a fabrication process) has decreased. This scaling down process generally provides benefits by increasing production efficiency and lowering associated costs. Such scaling down has also increased the complexity of processing and manufacturing ICs and, for these advancements to be realized, similar developments in IC processing and manufacturing are needed.

As integrated circuit (IC) technologies progress towards smaller technology nodes, multi-gate metal-oxide-semiconductor field effect transistor (multi-gate MOSFET, or multi-gate devices) have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Gate-all-around (GAA) transistors are examples of multi-gate devices that have become popular and promising candidates for high performance and low leakage applications. A GAA transistor has a gate structure that can extend, partially or fully, around a channel region to provide access to the channel region on two or more sides. While existing GAA transistors may be generally adequate for their intended purposes, they are not entirely satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, and 4 are perspective views of a workpiece at various fabrication stages, in accordance with some embodiments of the present disclosure.

FIGS. 5A, 6A, 7A, 8A, 9A, 10A, 11A, 12A, 13A, 14A, 15A, 16A, 17A, 18A, 19A, 20A, and 21A are X-Z cross-sectional views of the workpiece at various fabrication stages along line A-A′ of FIG. 4, in accordance with some embodiments of the present disclosure.

FIGS. 5B, 6B, 7B, 8B, 9B, 10B, 11B, 12B, 13B, 14B, 15B, 16B, 17B, 18B, 19B, 20B, and 21B are Y-Z cross-sectional views of the workpiece at various fabrication stages along line B-B′ of FIG. 4, in accordance with some embodiments of the present disclosure.

FIG. 21C is a Y-Z cross-sectional view of the workpiece at a fabrication stage along line C-C′ of FIG. 4, in accordance with some embodiments of the present disclosure.

FIG. 22 is an X-Z cross-sectional view of a workpiece at a fabrication stage along a line A-A′ of FIG. 4, in accordance with some alternative embodiments of the present disclosure.

FIGS. 23A, 24A, 25A, 26A, 27A, 28A, and 29A are X-Z cross-sectional views of the workpiece at various fabrication stages along line A-A′ of FIG. 4, in accordance with some alternative embodiments of the present disclosure.

FIGS. 23B, 24B, 25B, 26B, 27B, 28B, and 29B are Y-Z cross-sectional views of the workpiece at various fabrication stages along line B-B′ of FIG. 4, in accordance with some alternative embodiments of the present disclosure.

FIG. 29C is a Y-Z cross-sectional view of the workpiece at a fabrication stage along line C-C′ of FIG. 4, in accordance with some alternative embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally related to semiconductor structures, and more particularly to semiconductor structures with field-effect transistors (FETs), such as three-dimensional gate-all-around (GAA) transistors. Generally, a GAA transistor may include a plurality of vertically stacked nanostructures (e.g., nanosheets, nanowires, or nanorods) in a channel region of the transistor, thereby allowing better gate control, lowered leakage current, and improved scaling capability for various IC applications.

The nanostructure transistor (e.g., nanosheet transistor, nanowire transistor, multi-bridge channel, nano-ribbon FET, GAA transistor structures) described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

In advanced technology node, since the geometry size is decreased, a backside metal routing disposed on the backside of the device is provided, so that the frontside and backside metal routing can together provide better interconnection. The critical poly pitch (CPP) (the pitch between a gate and an adjacent gate) and the critical dimension (CD) of backside source/drain (S/D) contact of the GAA transistor are scaled down as the dimension of the GAA transistor continue to scale down. Since the CPP and the CD of backside S/D contact are scaled down, the resistance of the backside S/D contact is increased, and an accurate overlay control of the photolithography process for forming the backside S/D contact is required to avoid causing a short-circuit between the gate and the backside S/D contact. Therefore, a novel structure and fabricating method are needed to reduce the resistance of the backside S/D contact and mitigate the requirement of the overlay control for forming the backside S/D contact.

Embodiments of the present disclosure offer advantages over the existing art, though it is understood that other embodiments may offer different advantages, not all advantages are necessarily discussed herein, and no particular advantage is required for all embodiments. For example, embodiments discussed herein include structures and methods that include forming semiconductor material layers (e.g., SiGe layers) below the S/D features of the GAA transistor. The backside S/D contact may be formed by forming a first opening to expose the semiconductor material layer, selectively removing the semiconductor material layer to form a second opening exposing the S/D feature, and depositing a conductive material in the first and second openings. Since the second opening is formed by selectively removing the semiconductor material layer, the space occupied by the semiconductor material layer can be fully utilized to form the backside S/D contact, so as to reduce the resistance of the backside S/D contact and connect to the small source/drain feature reliably. It also keeps the backside S/D contact from contacting other conductive components to avoid causing a short-circuit. Furthermore, since the first opening is used to expose the semiconductor material layer, it can be formed greater than the semiconductor material layer, so that the resistance of the backside S/D contact formed inside can be reduced. Moreover, when the overlay shift is occurred, the first opening greater than the semiconductor material layer can still expose the semiconductor material layer, and thus the requirement of the overlay control can be mitigated.

The various aspects of the present disclosure will now be described in more detail with reference to the figures. For avoidance of doubts, the X-direction, the Y-direction, and the Z-direction in the figures are perpendicular to one another and are used consistently. Throughout the present disclosure, like reference numerals denote like features unless otherwise indicated.

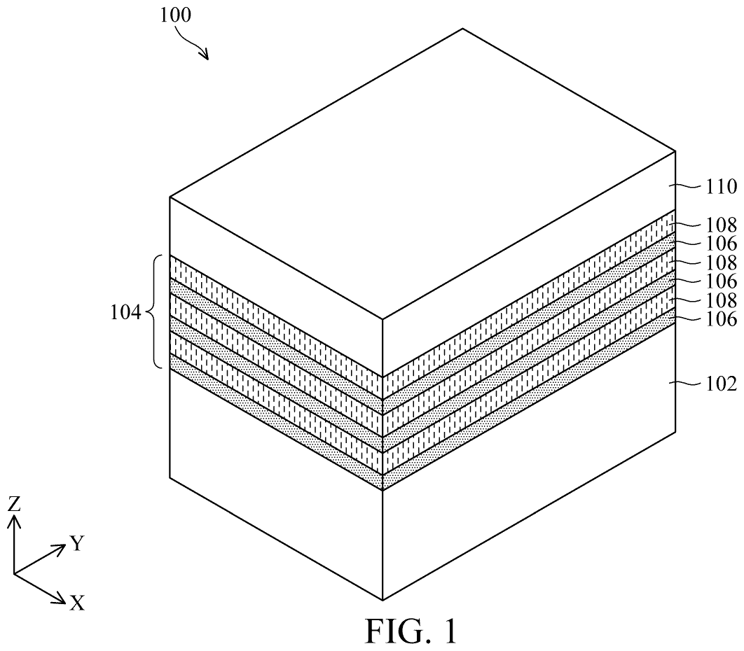

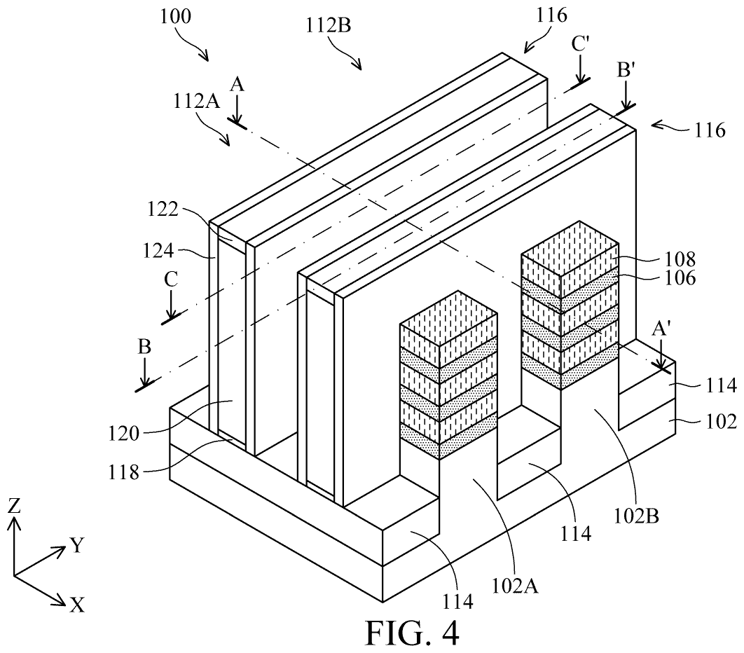

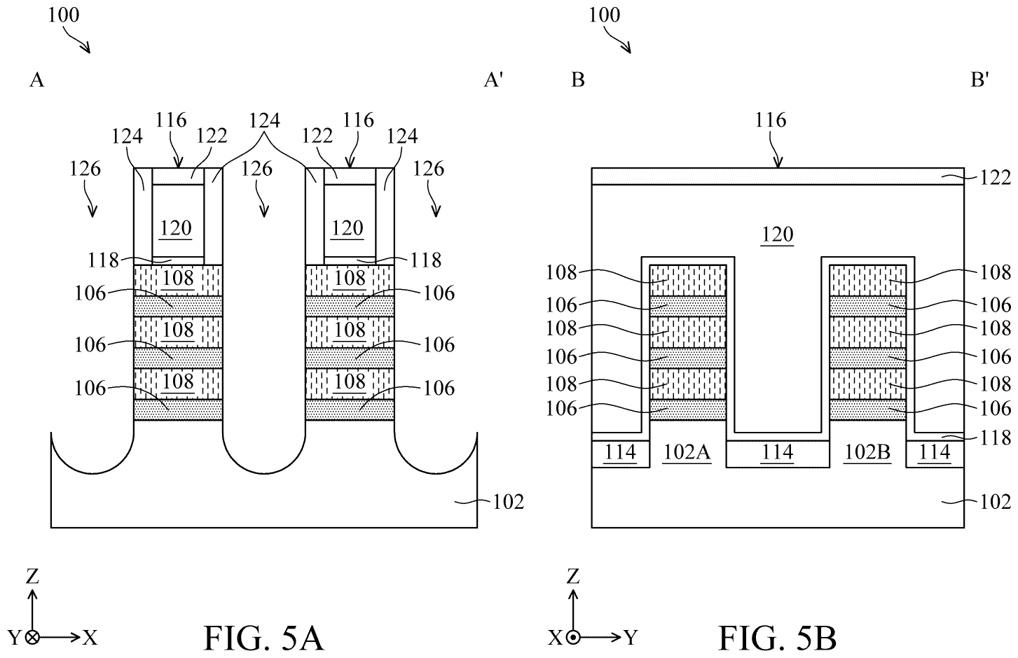

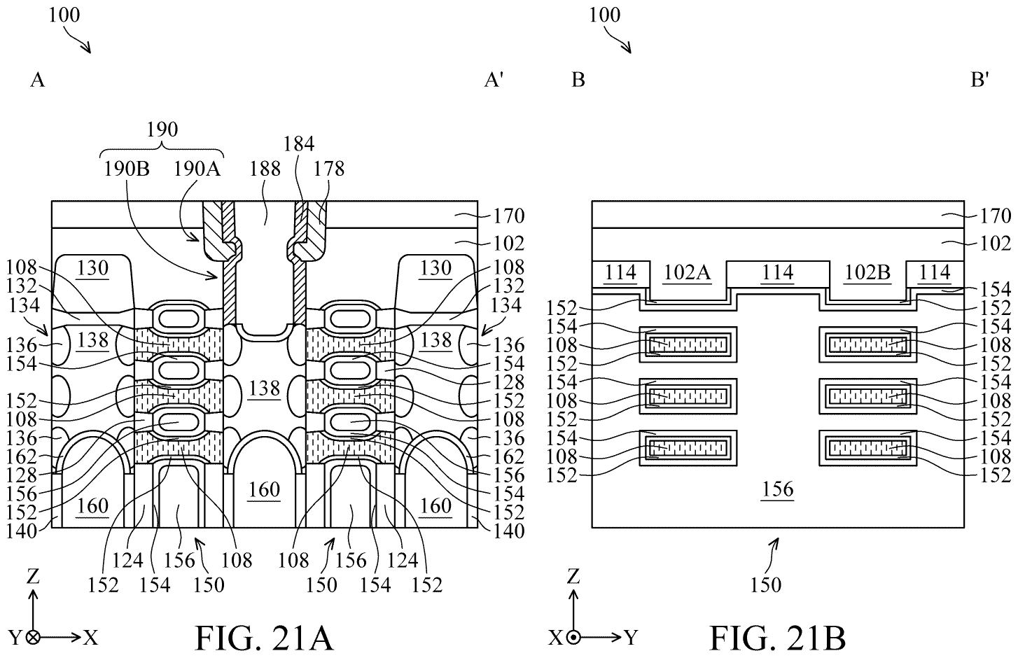

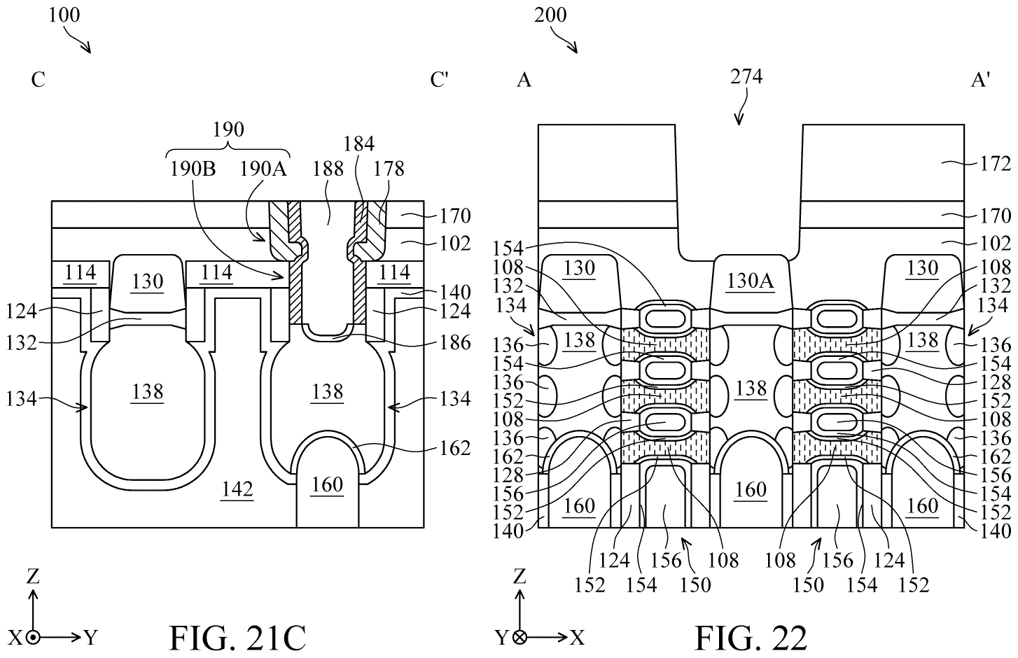

FIGS. 1, 2, 3, and 4 are perspective views of a workpiece 100 at various fabrication stages, in accordance with some embodiments. FIGS. 5A, 6A, 7A, 8A, 9A, 10A, 11A, 12A, 13A, 14A, 15A, 16A, 17A, 18A, 19A, 20A, and 21A are X-Z cross-sectional views of the workpiece 100 at various fabrication stages along line A-A′ of FIG. 4, in accordance with some embodiments. FIGS. 5B, 6B, 7B, 8B, 9B, 10B, 11B, 12B, 13B, 14B, 15B, 16B, 17B, 18B, 19B, 20B, and 21B are Y-Z cross-sectional views of the workpiece 100 at various fabrication stages along line B-B′ of FIG. 4, in accordance with some embodiments. FIG. 21C is a Y-Z cross-sectional view of the workpiece 100 at a fabrication stage along line C-C′ of FIG. 4, in accordance with some embodiments.

Referring to FIG. 1, the workpiece 100 includes a substrate 102 and a stack 104 over the substrate 102, in accordance with some embodiments. In some embodiments, the substrate 102 contains a semiconductor material, such as bulk silicon (Si). In some embodiments, the substrate 102 may include other semiconductors such as germanium (Ge), silicon germanium (SiGe), or a III-V semiconductor material. Example III-V semiconductor materials may include GaAs, InP, GaP, GaN, GaAsP, AlInAs, AlGaAs, GaInP, and InGaAs. The substrate 102 may also include an insulating layer, such as a silicon oxide layer, to have a silicon-on-insulator (SOI) structure or a germanium-on-insulator (GOI) structure.

In some embodiments, the substrate 102 may include one or more well regions for forming different types of devices. For example, the well regions may be n-type well regions doped with an n-type dopant (e.g., phosphorus (P) or arsenic (As)) or p-type well regions doped with a p-type dopant (e.g., boron (B) or indium (In)). The n-type and p-type well regions may be formed by using ion implantation or thermal diffusion. Since the workpiece 100 will be fabricated into a semiconductor structure 100 upon conclusion of the fabrication processes, the workpiece 100 may be referred to as the semiconductor structure 100 as the context requires.

In some embodiments, the stack 104 may include semiconductor layers 106 and semiconductor layers 108. In some embodiments, the semiconductor layers 106 and 108 are stacked in an alternating manner in the Z-direction. The semiconductor layers 106 and the semiconductor layers 108 may have different semiconductor compositions. In some embodiments, the semiconductor layers 106 are formed of silicon germanium (SiGe), and the semiconductor layers 108 are formed of silicon (Si). In these embodiments, the additional germanium content in the semiconductor layers 106 allows selective removal or recess of the semiconductor layers 106 without substantial damages to the semiconductor layers 108, so that the semiconductor layers 106 are also referred to as sacrificial layers.

In some embodiments, the semiconductor layers 106 and 108 are epitaxially grown over or on the substrate 102 using an epitaxial growth process such as vapor-phase epitaxy (VPE), metal-organic CVD (MOCVD), molecular beam epitaxy (MBE), although other deposition processes, such as chemical vapor deposition (CVD), low pressure CVD (LPCVD), plasma-enhanced CVD (PECVD), atomic layer deposition (ALD), ultrahigh vacuum CVD (UHVCVD), remote plasma CVD (RPCVD), a combination thereof, or the like, may also be utilized. The semiconductor layers 106 and the semiconductor layers 108 are formed alternatingly, one-after-another, to form the stack 104. It should be noted that, three layers of the semiconductor layers 106 and three layers of the semiconductor layers 108 are alternately and vertically arranged (or stacked) as shown in FIG. 1, which are for illustrative purposes only and are not intended to be limiting beyond what is specifically recited in the claims. The number of layers depends on the desired number of channel members for the semiconductor device. In some embodiments, there may be from 2 to 10 semiconductor layers 106 alternating with 2 to 10 semiconductor layers 108 in the stack 104.

For patterning purposes, the workpiece 100 may also include a hard mask layer 110 over the stack 104. The hard mask layer 110 may be a single layer structure or a multi-layer structure. In some embodiments, the hard mask layer 110 is a single layer structure and includes a silicon germanium layer. In some embodiments, the hard mask layer 110 is a multi-layer structure and includes a silicon nitride layer and a silicon oxide layer over the silicon nitride layer. In other embodiments, the hard mask layer 110 is a multi-layer structure and includes a silicon germanium layer and a silicon layer over the silicon germanium layer.

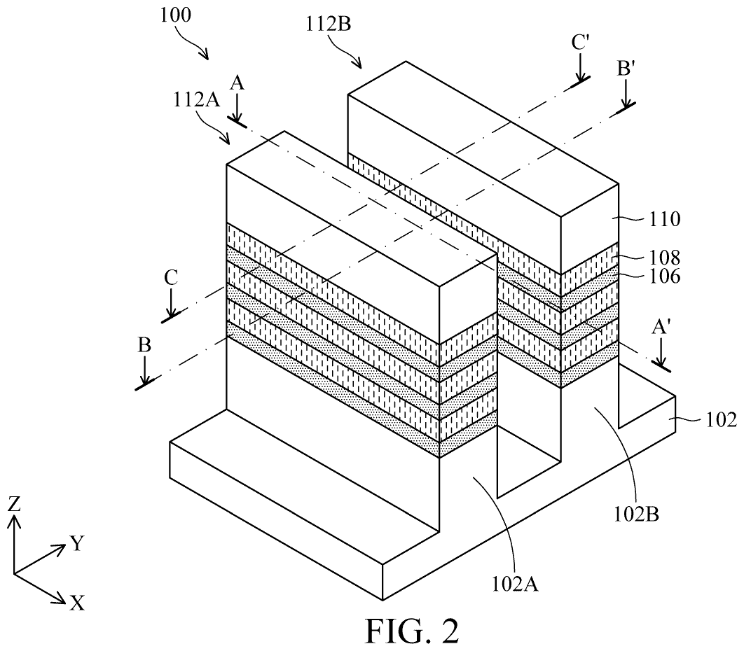

Referring to FIG. 2, the substrate 102, the stack 104, and the hard mask layer 110 are then patterned to form a fin structure 112A and a fin structure 112B (may be collectively referred to as fin structures 112) over the substrate 102, in accordance with some embodiments. In some embodiments, each of the fin structures 112 includes a base portion (base fins 102A and 102B) formed from a portion of the substrate 102 and a stack portion formed from the stack 104 over the base portion, as shown in FIG. 2. The stack portion includes the semiconductor layers 106 and the semiconductor layers 108 alternately stacked over the substrate 102. In some embodiments, the base fins 102A and 102B protrude from the substrate 102. Each of the fin structures 112 may extend lengthwise in the X-direction and extend vertically in the Z-direction over the substrate 102, and arranged in the Y-direction. In some embodiments, widths of the fin structures 112 along the Y-direction are the same. Although the two fin structures 112A and 112B are formed and shown herein, more fin structures may be formed, such as three or more fin structures.

The fin structures 112 may be patterned using suitable processes including photolithography processes and etching processes. The suitable processes may include double-patterning or multi-patterning processes. For example, in some embodiments, a material layer is formed over a substrate and patterned using a photolithography process. Spacers are formed alongside the patterned material layer using a self-aligned process. The material layer is then removed, and the remaining spacers, or mandrels, may then be used to pattern the fin structures 112 by etching the stack 104 and the substrate 102. The etching process may include dry etching, wet etching, reactive ion etching (RIE), and/or other suitable processes. In some embodiments, the photolithography processes include photoresist coating (e.g., spin-on coating), soft baking, mask aligning, exposure, post-exposure baking, developing the photoresist, rinsing, and drying (e.g., hard baking). In other embodiments, the photolithography processes may be implemented or replaced by other suitable methods, such as maskless photolithography, electron-beam (e-beam) writing, and ion-beam writing.

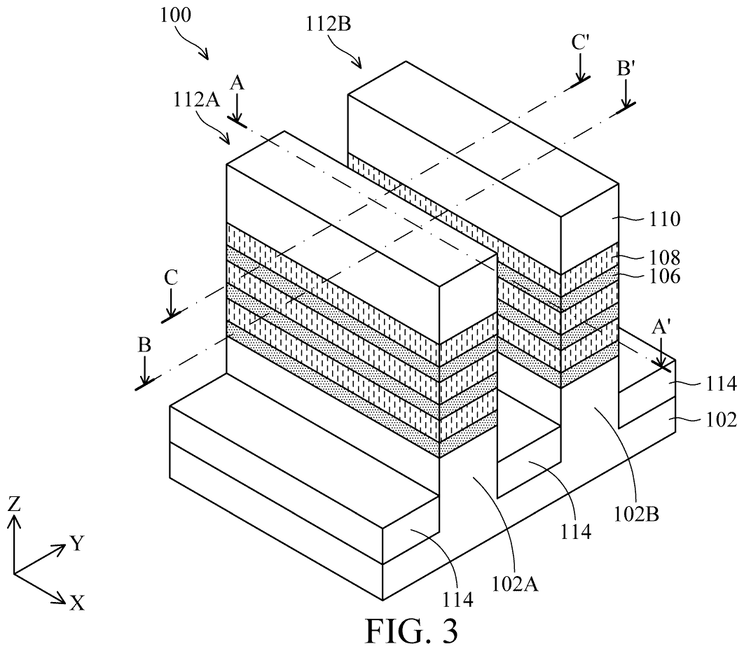

Referring to FIG. 3, isolation structure 114 are formed, in accordance with some embodiments. After the fin structures 112 are formed, the hard mask layer 110 over the fin structures 112 is removed and the isolation structures 114 are formed over the substrate 102. In some embodiments, the isolation structures 114 are formed between the fin structures 112. In other embodiments, the isolation structures 114 are formed around the fin structures 112. More specifically, the isolation structures 114 are formed between and around the base fins (e.g., base fins 102A and 102B) of the fin structures 112. The isolation structures 114 may also be referred to as shallow trench isolation (STI) feature.

In some embodiments, a dielectric material for the isolation structures 114 is first deposited over the workpiece 100. Specifically, the dielectric material is deposited and formed over the fin structures 112 and the substrate 102 to cover the fin structures 112 and the substrate 102. In some embodiments, the dielectric material is formed to wrap around the fin structures 112. In some embodiments, the dielectric material may include silicon oxide (SiO₂), silicon nitride (Si₃N₄), silicon oxynitride (SiON), fluorine-doped silicate glass (FSG), a low-k dielectric material, combinations thereof, and/or other suitable materials. Exemplary low-k dielectric materials include carbon doped silicon oxide, Black Diamond® (Applied Materials of Santa Clara, California), xerogel, aerogel, amorphous fluorinated carbon, parylene, BCB-based dielectric material, SiLK (Dow Chemical, Midland, Michigan), polyimide, other low-k dielectric materials, or combinations thereof.

In some embodiments, the dielectric material is deposited using a deposition process, such as a CVD, a subatmospheric CVD (SACVD), a flowable CVD (FCVD), an ALD, spin-on coating, and/or other suitable process. The deposited dielectric material is then thinned and planarized, for example by a chemical mechanical polishing (CMP) process, until top surfaces of the hard mask layer 110 is exposed (not shown). The planarized dielectric material is further recessed by a dry etching process, a wet etching process, and/or a combination thereof to form the isolation structures 114. In some embodiments, the stack portions of the fin structures 112 rise above the isolation structures 114 while the base fins 102A and 102B are surrounded by the isolation structures 114, as shown in FIG. 3. In other words, top surfaces (or topmost surfaces) of the substrate 102 are higher than the top surfaces of the isolation structures 114. In some embodiments, before the formation of the isolation structures 114, a liner layer may be conformally deposited over the substrate 102 using a deposition process, such as CVD, ALD, high-density plasma CVD (HDPCVD), MOCVD, RPCVD, plasma-enhanced CVD (PECVD), LPCVD, atomic layer CVD (ALCVD), atmospheric pressure CVD (APCVD), FCVD, or combinations thereof.

Referring to FIG. 4, dummy gate structures 116 may be formed over the fin structures 112 and over the isolation structures 114, in accordance with some embodiments. In some embodiments, the dummy gate structures 116 may be configured to extend lengthwise in the Y-direction and wrap around top surfaces and side surfaces of the fin structures 112, as shown in FIG. 4. In some embodiments, in order to form the dummy gate structures 116, a dummy gate dielectric material for dummy gate dielectric layers 118 is first formed over the fin structures 112 and over the isolation structures 114. In some embodiments, the dummy gate dielectric layers 118 may include, for example, a dielectric material such as a nitride (e.g., SiN, SiON), a carbide (e.g., SiC), an oxide (e.g., SiO₂), or some other suitable materials.

Then, in some embodiments, a dummy gate electrode material for dummy gate electrode layers 120 is formed over the dummy gate dielectric material. The dummy gate electrode material may include a conductive material selected from a group composed of polysilicon, W, Al, Cu, AlCu, Ti, TiAlN, TaC, TaCN, TaSiN, Mn, Zr, TiN, Ta, TaN, Co, Ni, and/or combinations thereof. The dummy gate electrode material and/or the dummy gate dielectric material may be formed by way of a thermal oxidation process and/or a deposition process (e.g., physical vapor deposition (PVD), CVD, PECVD, and ALD).

Afterward, hard mask layers 122 are formed over the dummy gate electrode material. In some embodiments, the hard mask layers 122 may be formed by using photolithography and removal (e.g., etching) processes. In some embodiments, the hard mask layers 122 may include photoresist materials or hard mask materials. In some embodiments, each of the hard mask layers 122 may include multiple layers, such as a silicon nitride layer and a silicon oxide layer. After the formation of the hard mask layers 122, a removal process (e.g., etching) may be performed to remove portions of the dummy gate electrode material for the dummy gate electrode layers 120 and the dummy gate dielectric material for the dummy gate dielectric layers 118 that are not directly underlie the hard mask layers 122, thereby forming the dummy gate structures 116. Each of the dummy gate structures 116 has the dummy gate dielectric layer 118, the dummy gate electrode layer 120, and the hard mask layer 122. The dummy gate dielectric layers 118 may also be referred to as dummy interfacial layers.

The dummy gate structures 116 may undergo a gate replacement process through subsequent processing to form metal gates, such as high-k metal gates, as discussed in greater detail below. FIG. 4 shows two dummy gate structures 116. In some embodiments, less or more dummy gate structures may be formed for one or more transistors sharing source/drain regions.

Still referring to FIG. 4, after the formation of the dummy gate structures 116, gate spacers 124 are formed on sidewalls of the dummy gate structures 116 and over the top surfaces of the fin structures 112, in accordance with some embodiments. In some embodiments, the gate spacers 124 are formed on opposite sidewalls of the fin structures 112, on the opposite sidewalls of the dummy gate structures 116, and over the top surface of the topmost semiconductor layer 108, as shown in FIG. 4. The gate spacers 124 may include silicon nitride (Si₃N₄), silicon oxide (SiO₂), silicon carbide (SiC), silicon oxycarbide (SiOC), silicon oxynitride (SiON), silicon carbon nitride (SiCN), silicon oxycarbon nitride (SiOCN), carbon doped oxide, nitrogen doped oxide, porous oxide, or combinations thereof. In some embodiments, the gate spacers 124 include a low-k dielectric material, such as those described herein. The gate spacers 124 may include a single layer or a multi-layer structure.

In some embodiments, the gate spacers 124 may be formed by conformally depositing a spacer layer of dielectric material over the fin structures 112 and the dummy gate structures 116, followed by an anisotropic etching process to remove top portions of the spacer layer from the top surfaces of the isolation structures 114, the fin structures 112, and the dummy gate structure 116. After the anisotropic etching process, the portions of the spacer layer on the sidewall surfaces of the fin structures 112 and the dummy gate structures 116 substantially remain and become the gate spacers 124. In some embodiments, the anisotropic etching process is a dry (e.g., plasma) etching process. Additionally or alternatively, the formation of the gate spacers 124 may also involve chemical oxidation, thermal oxidation, CVD, PVD, ALD, HDPCVD, MOCVD, RPCVD, PECVD, LPCVD, ALCVD, APCVD, FCVD, and/or other suitable methods. The gate spacers 402 may also be interchangeably referred to as top spacers.

Referring to FIGS. 5A and 5B, the fin structures 112 are recessed to form source/drain trenches 126 in the fin structures 112 (or passing through semiconductor layers 106 and 108) for source/drain regions, in accordance with some embodiments. The source/drain trenches 126 are formed on the opposite sides of the dummy gate structures 116 in the X-direction. Specifically, the source/drain trenches 126 may be formed by performing one or more etching processes to remove portions of the semiconductor layers 106 and 108 and the substrate 102 (e.g., base fins 102A and 102B) that do not vertically overlap or not be covered by the dummy gate structures 116 and the gate spacers 124.

In some embodiments, a single etchant may be used to remove the substrate 102 and the semiconductor layers 106 and 108. In other embodiments, multiple etchants may be used to perform the etching process. In some embodiments, portions of the substrate 102 are etched, so that the source/drain trenches 126 extend into the substrate and each has a concave surface in the substrate 102, as shown in FIG. 5A. In some embodiments, portions of the gate spacers 124 on opposite sidewalls of the fin structures 112 in the Y-direction are removed. In these embodiments, the height of the gate spacers 124 on opposite sidewalls of the fin structures 112 in the Y-direction are reduced (see FIG. 21C below).

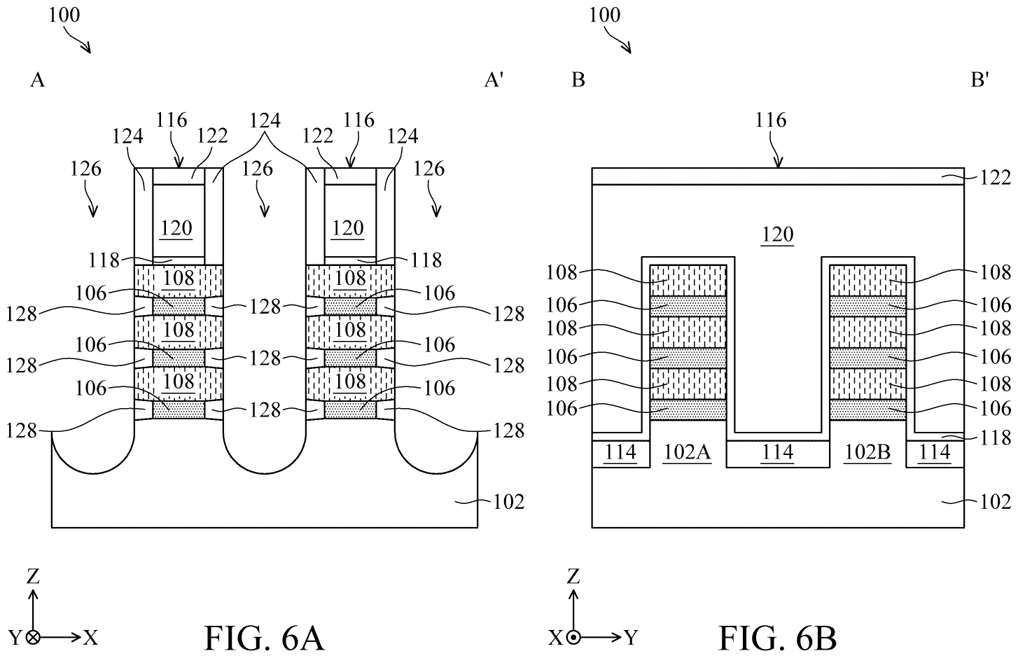

Referring to FIGS. 6A and 6B, the inner spacers 128 are formed between the semiconductor layers 108 as well as between the semiconductor layer 108 and the substrate 102, in accordance with some embodiments. In some embodiments, the semiconductor layers 106 exposed in the source/drain trenches 126 are partially recessed through a selective etching process, and the semiconductor layers 108 are not etched. More specifically, the selective etching process is performed that selectively etches the side portions of the semiconductor layers 106 below the gate spacers 124 through the source/drain trenches 126, with minimal etching (or substantially no etching) of the semiconductor layers 108 and the substrate 102. After the selective etching process, inner spacer recesses are vertically formed between the semiconductor layers 108 as well as between the semiconductor layers 108 and the substrate 102, below the gate spacers 124. The selective etching process may be a dry etching process, a wet etching process, other suitable etching process, or a combination thereof.

Next, in some embodiments, a spacer layer is conformally formed into the source/drain trenches 126 and the inner spacer recesses. More specifically, a deposition process is performed to form the spacer layer into the source/drain trenches 126 and the inner spacer recesses, such as CVD, PVD, ALD, HDPCVD, MOCVD, RPCVD, PECVD, LPCVD, ALCVD, APCVD, FCVD, other suitable methods, or combinations thereof. The spacer layer partially (and, in some embodiments, completely) fills the source/drain trenches 126 and fully fills the inner spacer recesses. The deposition process is configured to ensure that the spacer layer fills the inner spacer recesses. Furthermore, the spacer layer is also conformally formed on the gate spacers 124 and the isolation structures 114.

The spacer layer may include a material that is different than the materials of the semiconductor layers 108 and the gate spacers 124 to achieve desired etching selectivity during the etching process. In some embodiments, the spacer layer include a dielectric material that includes Si, O, C, N, other suitable material, or combinations thereof (e.g., SiO₂, SiON, SiOC, SiCN, SiOCN). In some embodiments, the spacer layer include a low-k dielectric material, such as those described herein. In some embodiments, the spacer layer includes a dielectric material having higher or lower k value (dielectric constant) than the gate spacers 124.

Then, in some embodiments, the inner spacers 128 are formed to fill the inner spacer recesses between the semiconductor layers 108 and between the semiconductor layer 108 and the substrate 102. More specifically, an etching process is performed to selectively etch the spacer layer to form the inner spacers 128 with minimal etching (or substantially no etching) of the semiconductor layers 108, the substrate 102, the dummy gate structures 116, and the gate spacers 124. The etching process may be an anisotropic etching process, such that portions of the spacer layer that do not vertically overlap or be covered by the dummy gate structures 116 and the gate spacers 124 are removed. The spacer layer on the gate spacers 124 and the isolation structures 114 are also removed.

In some embodiments, sidewalls of the inner spacers 128 are aligned to the sidewalls of the gate spacers 124 and the semiconductor layers 108. Therefore, the inner spacers 128 are formed on opposite sides of the dummy gate structure 116. In other embodiments, sidewalls of the inner spacers 128 have concave surfaces exposed by the source/drain trenches 126. In some embodiments, sidewalls of the inner spacers 128 in contact with the semiconductor layers 106 have convex surfaces.

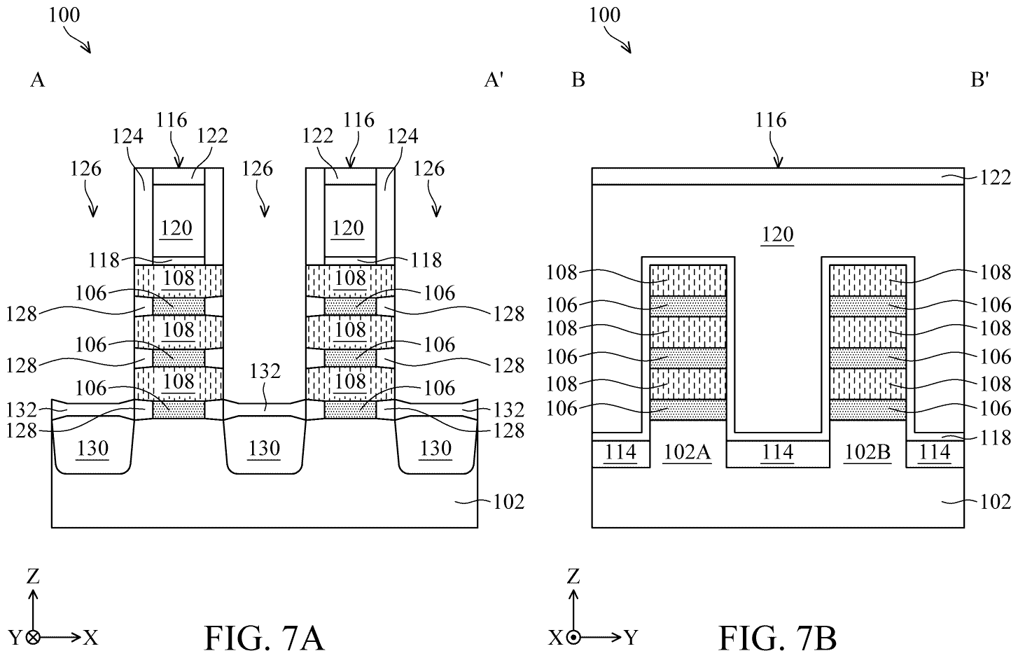

Referring to FIGS. 7A to 7D, semiconductor material layers 130 and bottom isolation layers 132 are formed in the lower parts of the source/drain trenches 126, in accordance with some embodiments. In some embodiments, the semiconductor material layers 130 are formed over the substrate 102 exposed in the source/drain trenches 126, and the bottom isolation layers 132 are formed over the semiconductor material layers 130. In these embodiments, the semiconductor material layers 130 are vertically between and in contact with the bottom isolation layers 132 and the substrate 102 in the Z-direction, and on opposite sides of the dummy gate structure 116 in the X-direction.

In some embodiments, the top surfaces of the semiconductor material layers 130 are higher than or equal to the top surface of the substrate 102, and lower than the bottom surfaces of the bottommost semiconductor layers 108. In some embodiments, the top surfaces of the semiconductor material layers 130 are higher than the top surfaces of the isolation structures 114. In some embodiments, the material of the semiconductor material layers 130 is SiGe and the material of the substrate 102 is silicon, so as to achieve desired etching selectivity during the removal of the semiconductor material layers 130, which will be discussed in greater detail below. In some embodiments, the semiconductor material layers 130 may be formed by using epitaxial growth process such as VPE, MOCVD, MBE, although other deposition processes, such as CVD, LPCVD, PECVD, ALD, UHVCVD, RPCVD, a combination thereof, or the like, may also be utilized.

In some embodiments, the bottom isolation layers 132 are formed on the semiconductor material layers 130. In some embodiments, the bottom isolation layers 132 have a dumbbell shape (or dog-bone shape), that is, each of the bottom isolation layers 132 includes end portions that have greater thickness than a middle portion between the end portions. In some embodiments, the end portions are in contact with the bottommost inner spacers 128. In some embodiments, the top surfaces of the bottom isolation layers 132 are lower than the bottom surfaces of the bottommost semiconductor layers 108, and the bottom surfaces of the bottom isolation layers 132 are higher than the topmost surfaces of the substrate 102. In other embodiments, the top surfaces of the bottom isolation layers 132 are above and the bottom surfaces of the bottom isolation layers 132 are under the topmost surfaces of the substrate 102.

In some embodiments, the dielectric material of the bottom isolation layers 132 may include Si₃N₄, SiO₂, SiC, SiOC, SiON, SiCN, SiOCN, high-k dielectrics, other suitable materials, or combinations thereof. In some embodiments, the bottom isolation layers 132 may be deposited by CVD, PVD, ALD, HDPCVD, MOCVD, RPCVD, PECVD, LPCVD, ALCVD, APCVD, other suitable methods, or combinations thereof.

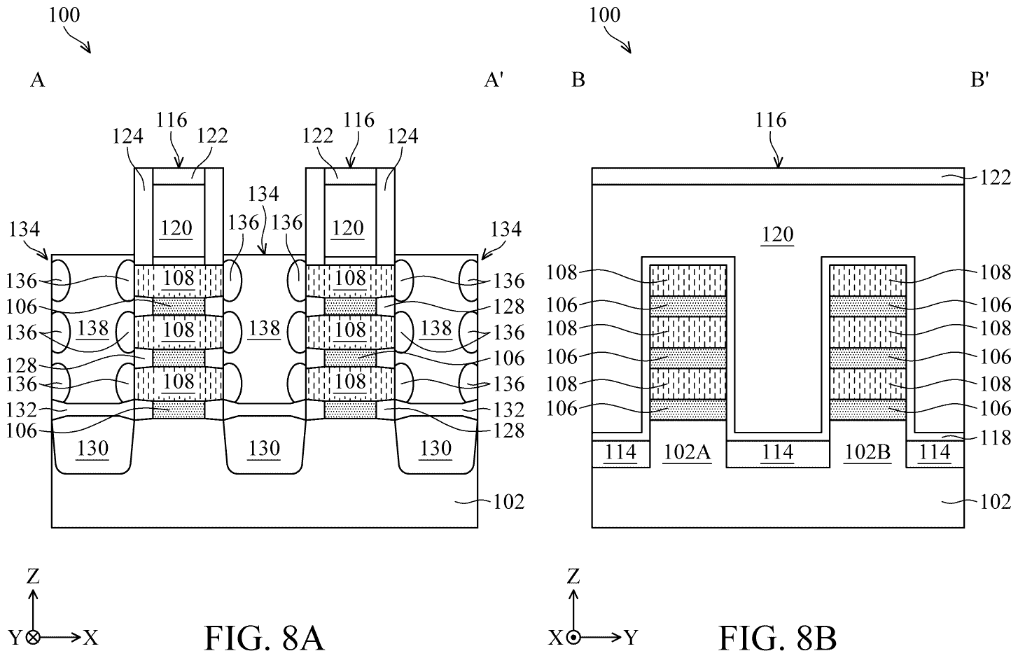

Referring to FIGS. 8A and 8B, source/drain features 134 are formed in the source/drain trenches 126 and on the bottom isolation layers 132, in accordance with some embodiments. The source/drain features 134 may be formed in the fin structures 112 and on the opposite sides of the dummy gate structures 116 in the X-direction. In some embodiments, the source/drain features 134 are connected to and in contact with the semiconductor layers 108. That is, the source/drain features 134 are attached to the opposite sides of the semiconductor layers 108. The source/drain features 134 may also be referred to as source/drain, or source/drain regions. In some embodiments, source/drain feature(s) 134 may refer to a source or a drain, individually or collectively dependent upon the context. In some embodiments, the semiconductor layers 108 serve as channels to connect one source/drain feature 134 to another source/drain feature 134. Therefore, the semiconductor layers 108 may also be referred to as channels, channel layers, or channel members.

In some embodiments, each of the source/drain features 134 includes first epitaxial layers 136 formed on the end portions of the semiconductor layers 108 and a second epitaxial layer 138 formed on the first epitaxial layers 136, as shown in FIG. 8A. In some embodiments, the first epitaxial layers 136 are in a discontinuous form that the first epitaxial layers 136 are separated and the first epitaxial layers 136 do not physically contact or merge together. In some embodiments, the first epitaxial layers 136 may have a height that is about the same as or greater than a thickness of the adjacent semiconductor layers 108. For example, the first epitaxial layers 136 may extend above and/or below the adjacent semiconductor layers 108. In further embodiments, the first epitaxial layers 136 may extend on the inner spacers 128 and/or on the gate spacers 124. In some embodiments, the first epitaxial layers 136 may have a convex shape. In some embodiments, the first epitaxial layers 136 may have a shape that is similar to a segment of a circle, a segment of an ellipse, a triangle, or another shape. In some embodiments, the bottommost first epitaxial layers 136 are in contact with the bottom isolation layers 132. In some embodiments, second epitaxial layer 138 formed on the first epitaxial layers 136 may have top surfaces that extend higher than the top surfaces of the topmost semiconductor layers 108 (e.g., in the Z-direction).

In other embodiments, the first epitaxial layers 136 are in a form of continuous layer. The first epitaxial layers 136 may extend continuously along sidewalls of the source/drain trenches 126. For example, the first epitaxial layers 136 may cover sidewalls of the semiconductor layers 108 within the source/drain trenches 126 and cover sidewalls of the inner spacers 128 that are between the semiconductor layers 108. The first epitaxial layers 136 may extend continuously along surfaces from a sidewall of the semiconductor layers 108 that are closest to the substrate 102 to a sidewall of the semiconductor layers 108 that are farthest from the substrate 102.

In some embodiments, the first epitaxial layers 136 and the second epitaxial layers 138 include the same semiconductor material but with different constituent concentrations. The semiconductor material may include silicon, germanium, silicon germanium, other suitable semiconductor material, or combinations thereof. In some embodiments where the source/drain features 134 are configured to form p-type GAA transistors, the first epitaxial layers 136 and the second epitaxial layers 138 include p-doped silicon germanium but with different p-type concentrations. For example, the first epitaxial layers 136 may have a p-type dopant concentration (e.g., a boron concentration) of about 1×10²⁰/cm³ to about 5×10²⁰/cm³, and the second epitaxial layers 138 may have a p-type dopant concentration (e.g., a boron concentration) of about 5×10²⁰/cm³ to about 2×10²¹/cm³.

In some embodiments where the source/drain features 134 are configured to form n-type GAA transistors, the first epitaxial layers 136 and the second epitaxial layers 138 include n-doped silicon but with different n-type concentrations. For example, the first epitaxial layers 136 may have an n-type dopant concentration (e.g., a phosphorous concentration or an arsenic concentration) of about 1×10²⁰/cm³ to about 5×10²⁰/cm³, and the second epitaxial layers 138 may have an n-type dopant concentration (e.g., a phosphorous concentration or an arsenic concentration) of about 5×10²⁰/cm³ to about 2×10²¹/cm³.

In some embodiments, the first epitaxial layers 136 are epitaxially grown from the end portions of the semiconductor layers 108 exposed by the source/drain trenches 126 using an epitaxial growth process. In some embodiments, the second epitaxial layers 138 are epitaxially grown from the first epitaxial layers 136 using an epitaxial growth process. The epitaxial growth process for forming the first epitaxial layers 136 and the second epitaxial layers 138 may be VPE, MOCVD, MBE, or other deposition processes, such as CVD, LPCVD, PECVD, ALD, UHVCVD, RPCVD, combinations thereof, or the like. In some embodiments, the first epitaxial layers 136 and the second epitaxial layers 138 are doped in-situ or ex-situ. In some embodiments, one or more annealing processes may be performed to activate the dopants in the first epitaxial layers 136 and the second epitaxial layers 138. The annealing processes may include rapid thermal annealing (RTA) and/or laser annealing processes.

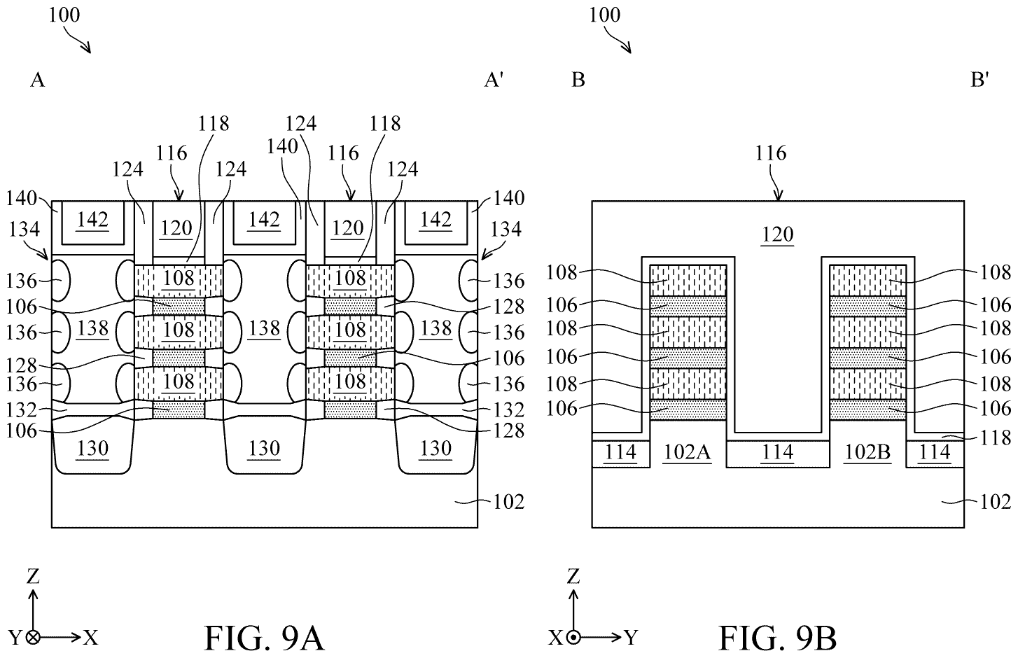

Referring to FIGS. 9A and 9B, a contact etch stop layer (CESL) 140 over the source/drain features 134 and an interlayer dielectric (ILD) layer 142 over the CESL 140 are formed to fill the space between the gate spacers 124, in accordance with some embodiments. In some embodiments, the CESL 140 is conformally formed on the sidewalls of the gate spacers 124 and over the top surfaces of the source/drain features 134, as shown in FIG. 9A. The ILD layer 142 is formed over and between the CESL 140 to fill the spaces between the CESL 140 or between the gate spacers 124.

The CESL 140 may include a material that is different than ILD layer 142. The CESL 140 may include La₂O₃, Al₂O₃, SiOCN, SiOC, SiCN, SiO₂, SiC, ZnO, ZrN, Zr₂Al₃O₉, TiO₂, TaO₂, ZrO₂, HfO₂, Si₃N₄, Y₂O₃, AlON, TaCN, ZrSi, or other suitable materials. The CESL 140 may be formed by CVD, PVD, ALD, HDPCVD, MOCVD, RPCVD, PECVD, LPCVD, ALCVD, APCVD, FCVD, or other suitable methods. The ILD layer 142 may include tetraethylorthosilicate (TEOS) formed oxide, un-doped silicate glass, or doped silicon oxide such as borophosphosilicate glass (BPSG), FSG, phosphosilicate glass (PSG), boron doped silicon glass (BSG), a low-k dielectric material, other suitable dielectric material, or combinations thereof. The ILD layer 142 may be formed by CVD, PVD, ALD, HDPCVD, MOCVD, RPCVD, PECVD, LPCVD, ALCVD, APCVD, FCVD, or other suitable methods.

Subsequent to the deposition of the CESLs 140 and the ILD layers 142, a CMP process and/or some other planarization process is performed on the CESLs 140, the ILD layers 142, the gate spacers 124, and the hard masks layer 122 until the top surfaces of the dummy gate electrode layers 120 are exposed. In some embodiments, portions of the dummy gate electrode layers 120 are removed after the planarization process.

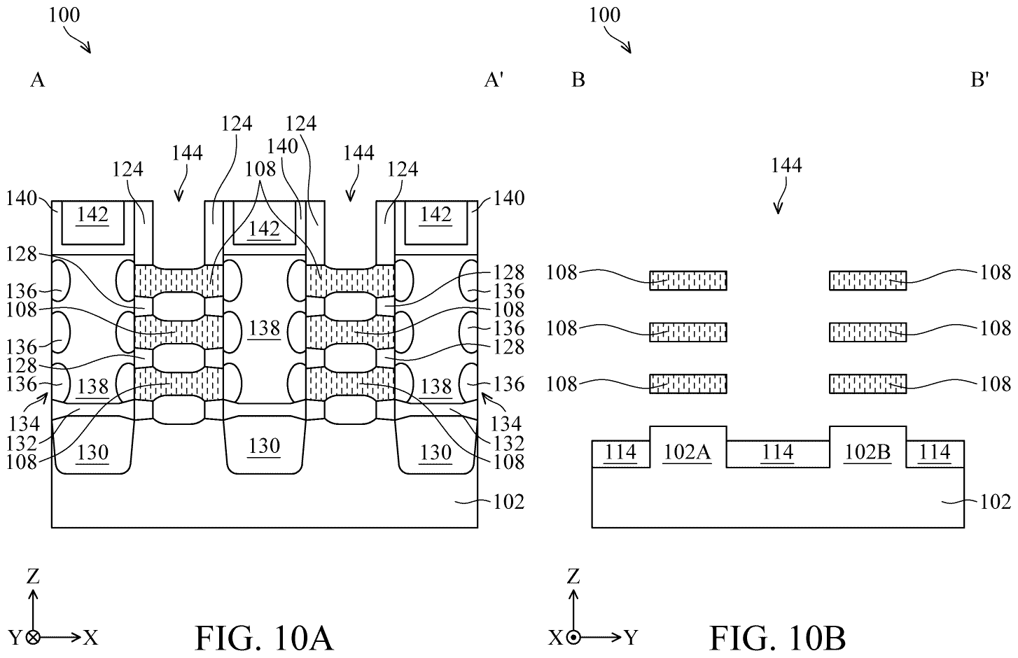

Referring to FIGS. 10A and 10B, the dummy gate structures 116 are selectively removed through any suitable photolithography and etching processes, in accordance with some embodiments. In some embodiments, the photolithography process may include forming a photoresist layer (resist), exposing the resist to a pattern, performing a post-exposure bake process, and developing the resist to form a masking element, which exposes a region including the dummy gate structures 116. Then, the dummy gate structures 116 are selectively etched through the masking element. The gate spacers 124 may be used as the masking element or a part thereof. Etch selectivity may be achieved by selecting appropriate etching chemicals, and the dummy gate structures 116 may be removed without substantially affecting the CESL 140 and the ILD layer 142. The removal of the dummy gate structures 116 creates gate trenches 144, as shown in FIGS. 10A and 10B. The gate trenches 144 exposes the top surfaces of the topmost semiconductor layers 108 that underlie the dummy gate structures 116.

Still referring to FIGS. 10A and 10B, the semiconductor layers 106 are selectively removed through the gate trenches 144 to enlarge the gate trenches 144, using a wet or dry etching process for example, in accordance with some embodiments. After the semiconductor layers 106 are selectively removed, the semiconductor layers 108 are exposed in the gate trenches 144 to form the nanostructures stacked on top of each other. As such, the semiconductor layers 108 may be referred to as nanostructures. Such a process may also be referred to as a wire/nanowire/nanosheet release process, or a wire/nanowire/nanosheet formation process.

In some embodiments, the semiconductor layers 108 are stacked over and spaced apart from each other in the Z-direction. Specifically, the semiconductor layers 108 are suspended over and vertically arranged over the substrate 102 in the Z-direction and constitute vertical stacks. In some embodiments, portions of the semiconductor layers 108 exposed in the gate trenches 144 may be partially etched during the removal of the semiconductor layers 106. For example, each of the semiconductor layers 108 may include end portions covered by the inner spacers 128 and the gate spacers 124, and include a middle portion between the end portions and exposed by the gate trench 144. The middle portions exposed in the gate trenches 144 may be partially etched during the removal of the semiconductor layers 106, so that the end portions have greater thickness than the middle portion. For example, after the removal of the semiconductor layers 106, each of the semiconductor layers 108 may have a dumbbell shape (or dog-bone shape), as shown in FIG. 10A.

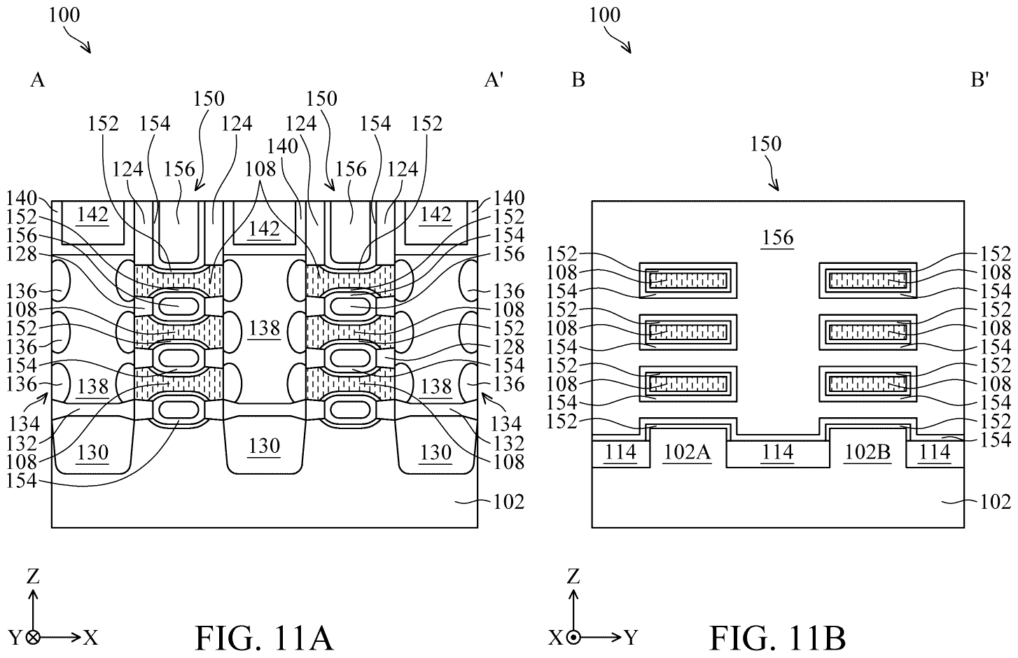

Referring to FIGS. 11A and 11B, gate structures 150 are formed in the gate trenches 144 to wrap around each of the exposed semiconductor layers 108, in accordance with some embodiments. In some embodiments, the gate structures 150 extend in the Y-direction. In some embodiments, the source/drain features 134 are formed on opposite sides of the gate structures 150 in the X-direction.

In some embodiments, the gate structures 150 each includes interfacial layers 152 formed on the surfaces of the semiconductor layers 108 to wrap around the exposed semiconductor layers 108, and formed on the exposed surfaces of the base fins 102A and 102B. In some embodiments, the interfacial layers 152 may include a dielectric material such as SiO₂, HfSiO, or SiON. The interfacial layers 152 may be formed by chemical oxidation, thermal oxidation, CVD, PVD, ALD, HDPCVD, MOCVD, RPCVD, PECVD, LPCVD, ALCVD, APCVD, FCVD, and/or other suitable method.

In some embodiments, the gate structures 150 each includes a gate dielectric layer 154 and a gate electrode layer 156 over the gate dielectric layer 154. In some embodiments, the gate dielectric layers 154 are formed on the interfacial layers 152 to wrap around the semiconductor layers 108. In further embodiments, the gate dielectric layers 154 are also formed on the sidewalls of the inner spacers 128 and the gate spacers 124, and over the top surfaces of the isolation structures 114 and the interfacial layers 152 formed on the base fins 102A and 102B.

In some embodiments, the gate dielectric layers 154 may include a dielectric material, such as SiOCN, SiOC, SiCN, SiO₂, SiN, SiC, or other suitable materials. In some embodiments, the gate dielectric layers 154 may include a high-k dielectric material that has a dielectric constant greater than a dielectric constant of SiO₂, which is approximately 3.9. For example, the gate dielectric layers 154 may include hafnium oxide (HfO₂), which has a dielectric constant in a range from about 18 to about 40. Alternatively, the gate dielectric layers 154 may include other high-k dielectrics, such as TiO₂, HfZrO, Ta₂O₃, HfSiO4, ZrO₂, ZrSiO₂, LaO, AlO, ZrO, TiO, Ta₂O₅, Y₂O₃, SrTiO₃ (STO), BaTiO₃ (BTO), BaZrO, HfLaO, HfSiO, LaSiO, AlSiO, HfTaO, HfTiO, (Ba,Sr)TiO₃ (BST), Al₂O₃, Si₃N₄, SiON, combinations thereof, or other suitable materials. The gate dielectric layers 154 may be formed by CVD, PVD, ALD, HDPCVD, MOCVD, RPCVD, PECVD, LPCVD, ALCVD, APCVD, FCVD, oxidation, and/or other suitable methods.

In some embodiments, the gate electrode layers 156 are formed to fill the remaining spaces of the gate trenches 144, and over the gate dielectric layers 154 in such a way that the gate electrode layers 156 wrap around the gate dielectric layer 154, the interfacial layers 152, and the semiconductor layers 108. The gate electrode layers 156 each may include a single layer or a multi-layer structure. In some embodiments, the gate electrode layers 156 each may include a capping layer, a barrier layer, work function metal layers, and a fill material. The gate electrode layers 156 may be formed using a deposition process such as CVD, PVD, ALD, HDPCVD, MOCVD, RPCVD, PECVD, LPCVD, ALCVD, APCVD, FCVD, or the like, although any suitable deposition process may be used.

The capping layer may be formed of a metallic material such as TaN, Ti, TiAlN, TiAl, Pt, TaC, TaCN, TaSiN, Mn, Zr, TiN, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The barrier layer may be formed of a material different from the capping layer. In some embodiments, the barrier layer may be formed of a material such as one or more layers of a metallic material. For example, the metallic material may be TiN, TaN, Ti, TiAlN, TiAl, Pt, TaC, TaCN, TaSiN, Mn, Zr, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like.

The work function layers may include conductive materials tuned to have a desired work function (e.g., an n-type work function or a p-type work function), such as n-type work function materials and/or p-type work function materials. In some embodiments, the n-type and p-type work function metal layers may include a material such as such as W, Al, Cu, TiN, Ti, TiAlN, TiAl, Pt, Ta, TaN, Co, Ni, TaC, TaCN, TaSiN, TaSi₂, NiSi₂, Mn, Zr, ZrSi₂, Ru, AlCu, Mo, MoSi₂, WN, other suitable work function materials, or combinations thereof. In some embodiments, the fill material may include a suitable conductive material, such as Al, W, and/or Cu.

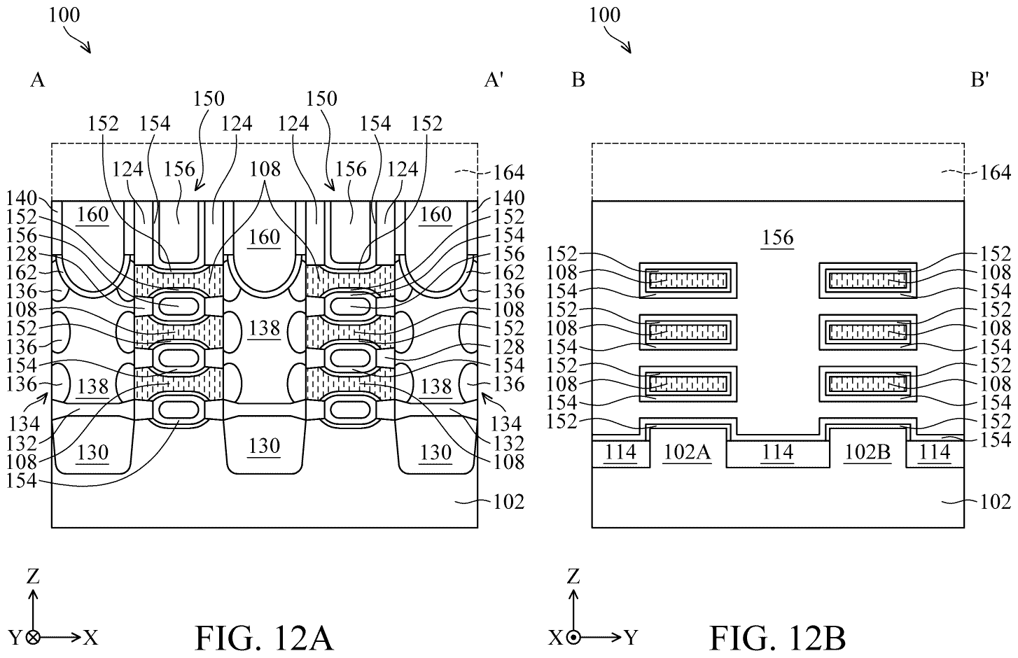

Referring to FIGS. 12A and 12B, source/drain contacts 160 and corresponding silicide layers 162 are formed on the frontside of the workpiece 100, in accordance with some embodiments. In some embodiments, the source/drain contacts 160 are formed to pass through the ILD layer 142, the CESLs 140, and portions of the source/drain features 134, so as to contact and electrically connect the source/drain features 134. The formation of the source/drain contacts 160 may include forming contact openings passing through the ILD layer 142 and the CESLs 140 and partially extending into the source/drain features 134, so as to expose the source/drain features 134.

Next, in some embodiments, the silicide layers 162 are formed on the exposed surfaces of the source/drain features 134 in the contact openings. In some embodiments, the silicide layers 162 are formed by depositing metal layers on the source/drain features 134, and heating the workpiece 100 to cause constituents of the source/drain features 134 to react with metal constituents of the metal layers. In some embodiments, the silicide layers 162 may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), or other suitable compounds.

Afterwards, in some embodiments, a conductive material of the source/drain contacts 160 may be deposited in the contact openings and on the silicide layers 162 by a deposition process, so as to form the source/drain contacts 160. That is, the contact openings are filled with the conductive material to form the source/drain contacts 160. The source/drain contacts 160 may include a conductive material such as Al, Cu, W, Co, Ti, Ta, Ru, Rh, Ir, Pt, Mo, TiN, TiAl, TiAlN, TaN, TaC, combinations of these, or the like, although any suitable material may be deposited using a deposition process such as sputtering, CVD, PVD, ALD, HDPCVD, MOCVD, RPCVD, PECVD, LPCVD, ALCVD, APCVD, FCVD, electroplating, electroless plating, or the like. In some embodiments, the source/drain contacts 160 may each include a single conductive material layer or multiple conductive layers. In some embodiments, the formation of the contact openings for the source/drain contacts 160 partially recesses the second epitaxial layers 138 and the topmost first epitaxial layers 136, and thus the source/drain contacts 160 and the silicide layers 162 formed in the contact openings are in contact with the second epitaxial layers 138 and the topmost first epitaxial layers 136, as shown in FIG. 12A.

Still referring to FIGS. 12A and 12B, a frontside interconnection structure 164 is formed on the frontside of the workpiece 100, in accordance with some embodiments. For the purpose of simplicity and clarity, the frontside interconnection structure 164 is illustrated as a dashed box. In some embodiments, the frontside interconnection structure 164 includes one or more inter-metal dielectric (IMD) layers formed over the ILD layer 142, the source/drain contacts 160, and the gate structures 150. In some embodiments, the method and material used in forming the IMD layers are the same as or similar to those of the ILD layer 142, and are not repeated herein. In some embodiments, the IMD layers may include multiple dielectric materials.

In some embodiments, the frontside interconnection structure 164 includes a plurality of vias (e.g., including source/drain vias, gate vias, vias connecting between different metal layers, and the like) and a plurality of metal layers (e.g., including metal conductor) formed in the IMD layers. The plurality of vias and the plurality of metal layers connect the gate structures 150 and the source/drain contacts 160 to various circuit components, so as to constitute the interconnection of the semiconductor device. In some embodiments, the method and material used in forming the plurality of vias and the plurality of metal layers are the same as or similar to those of the source/drain contacts 160, and are not repeated herein.

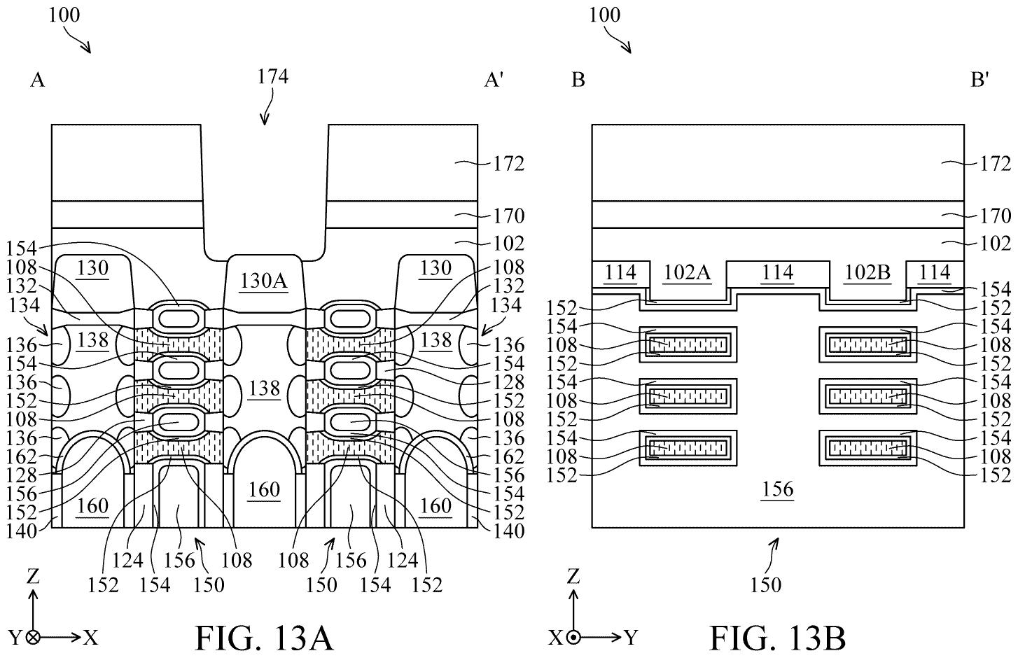

Referring to FIGS. 13A and 13B, the workpiece 100 is flipped, and a portion of the substrate 102 is removed from the backside of the workpiece 100, in accordance with some embodiments. In some embodiments, a carrier wafer may be bonded to the frontside of the workpiece 100 before flipping. Then, in some embodiments, the substrate 102 is thinned (or partially removed) from the backside of the workpiece 100 by a selective etching process or a CMP process. It should be noted that, for the purpose of simplicity, the frontside interconnection structure 164 formed on the frontside of the workpiece 100 is omitted from the FIGS. 13A and 13B and the subsequent figures.

Still referring to FIGS. 13A and 13B, after thinning the substrate 102, a hard mask layer 170 is formed on the backside of the workpiece 100 (i.e., on the thinned substrate 102), and a hard mask layer 172 is formed on the hard mask layer 170, in accordance with some embodiments. In some embodiments, the material of the hard mask layers 170 and 172 may include silicon nitride (Si₃N₄), SiO₂, SiC, SiOC, SiON, SiCN, SiOCN, high-k dielectrics, other suitable materials, or combinations thereof. In some embodiments, the material of the hard mask layers 170 is different than the material of the hard mask layers 172. In some embodiments, the hard mask layers 170 and 172 may be formed by CVD, PVD, ALD, HDPCVD, MOCVD, RPCVD, PECVD, LPCVD, ALCVD, APCVD, FCVD, or other suitable methods.

Still referring to FIGS. 13A and 13B, an opening 174 is formed on the backside of the workpiece 100 to expose one of the semiconductor material layers 130, in accordance with some embodiments. It should be noted that, for the purpose of clarity and simplicity, the semiconductor material layers 130 exposed by the opening 174 is referred to as the semiconductor material layer 130A below. In some embodiments, one or more photolithography and etching processes are performed to etch the hard mask layers 170 and 172 and the substrate 102, so as to form the opening 174 that exposes the semiconductor material layer 130A. In some embodiments, the etching processes may be dry etching processes, wet etching processes, other suitable etching processes, or combinations thereof. In some embodiments, the width of the opening 174 is greater than the width of the semiconductor material layer 130A in the X-direction, so as to fully expose the semiconductor material layer 130A, as shown in FIG. 13A. In some embodiments, since the width of the opening 174 is greater than the width of the semiconductor material layer 130A, the opening 174 vertically overlap with the inner spacers 128. In further embodiments, the width of the opening 174 is greater than the width of the semiconductor material layer 130A in the Y-direction.

In some embodiments, the end portion of the semiconductor material layer 130A is protruded from the bottom of the opening 174, as shown in FIG. 13A. That is, the end portion of the semiconductor material layer 130A is exposed in the opening 174, and the other portion of the semiconductor material layer 130A is still surrounded by the substrate 102. In other embodiments, the semiconductor material layer 130A is also partially etched, such that the surface of the semiconductor material layer 130A exposed in the opening 174 is substantially coplanar with the bottom surface of the opening 174.

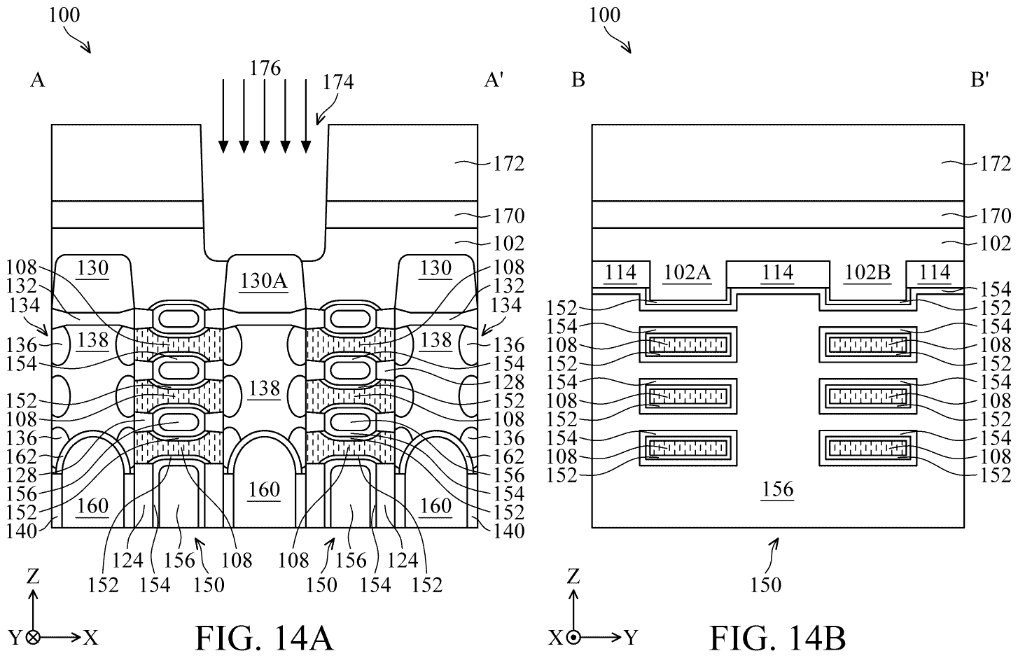

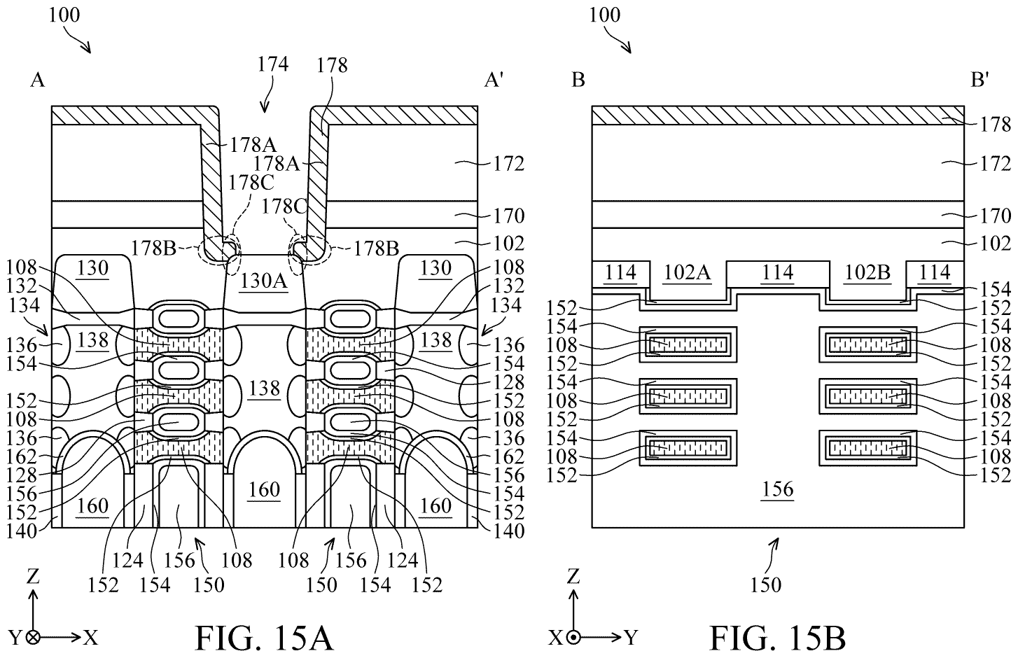

Referring to FIGS. 14A and 14B, an inhibitor 176 is introduced into the opening 174, in accordance with some embodiments. In some embodiments, the inhibitor 176 is added into the opening, and then absorbs on the surface of the semiconductor material layer 130A that is exposed in the opening 174. The inhibitor 176 may suppress the deposition or growth of the material of the insulating layer 178 (see FIGS. 15A and 15B). In some embodiments, the materials of the semiconductor material layers 130, the inhibitor 176, and the insulating layer 178 are configured so that the insulating layer 178 will not be formed on the semiconductor material layer 130A which absorbs the inhibitor 176. Since the inhibitor 176 is absorbed on the surface of the semiconductor material layer 130A, it prevents the insulating layer 178 (see FIGS. 15A and 15B) from depositing on or growing from the surface of the semiconductor material layer 130A exposed in the opening 174.

Referring to FIGS. 15A and 15B, the insulating layer 178 is formed on the hard mask layer 172 and in the opening 174, in accordance with some embodiments. In some embodiments, the insulating layer 178 is conformally formed on the top surface of the hard mask layer 172 and the sidewall of the opening 174. In some embodiments, for the bottom of the opening 174, since the inhibitor 176 is absorbed on the surface of the semiconductor material layer 130A, the insulating layer 178 is formed on the portion of the bottom surface of the opening 174 that is formed by the substrate 102, without forming on the surface of the semiconductor material layer 130A exposed in the opening 174. Therefore, the insulating layer 178 is formed on sidewall of the opening 174, and formed on the portion of the bottom surface of the opening 174 that is formed by the substrate 102 and surrounds the semiconductor material layer 130A, as shown in FIG. 15A. In FIG. 15A, the sidewall of the opening 174 includes the materials of the hard mask layers 170 and 172 and the substrate 102. In some embodiments, the opening 174 also passes through and exposes portions of the isolation structures 114, so that the sidewall of the opening 174 further includes the material of the isolation structures 114. In these embodiments, the insulating layer 178 is also formed on the material of the isolation structures 114.

In some embodiments, the insulating layer 178 may be divided into a main portion 178A and a protrusion portion 178B below the main portion 178A. In some embodiments, the protrusion portion 178B is formed on the portion of the bottom surface of the opening 174 that is formed by the substrate 102, and the main portion 178A is formed over the protrusion portion 178B and on the sidewall of the opening 174. In some embodiments, the dimensions of the protrusion portion 178B is greater than the dimensions of the main portion 178A in the X-direction and the Y-direction. In some embodiments, the protrusion portion 178B further includes a tip portion 178C that is over and slightly overlaps with the semiconductor material layer 130A, while most of the surface of the semiconductor material layer 130A is still exposed in the opening 174, as shown in FIG. 15A. In some embodiments, the thickness of the tip portion 178C is smaller than the thickness of the other portion of the protrusion portion 178B in the Z-direction.

In some embodiments, the insulating layer 178 is conformally formed on the top surface of the hard mask layer 172, on the sidewall of the opening 174, and on the portions of the bottom surface of the opening 174 that is formed by the substrate 102. Since the inhibitor 176 is absorbed on the surface of the semiconductor material layer 130A, the semiconductor material layer 130A is still exposed in the opening 174 after forming the insulating layer 178. The insulating layer 178 may include La₂O₃, Al₂O₃, SiOCN, SiOC, SiCN, SiO₂, SiC, ZnO, ZrN, Zr₂Al₃O₉, TiO₂, TaO₂, ZrO₂, HfO₂, Si₃N₄, Y₂O₃, AlON, TaCN, ZrSi, or other suitable materials. The insulating layer 178 may be formed by CVD, PVD, ALD, HDPCVD, MOCVD, RPCVD, PECVD, LPCVD, ALCVD, APCVD, FCVD, or other suitable methods. Since the insulating layer 178 is selectively formed on the materials other than the semiconductor material layer 130A absorbing the inhibitor 176, the insulating layer 178 may also be referred to as selective insulator. In some embodiments, after the formation of the insulating layer 178, a cleaning process is performed to remove the inhibitor 176 from the opening 174, such as from the surface of the semiconductor material layer 130A.

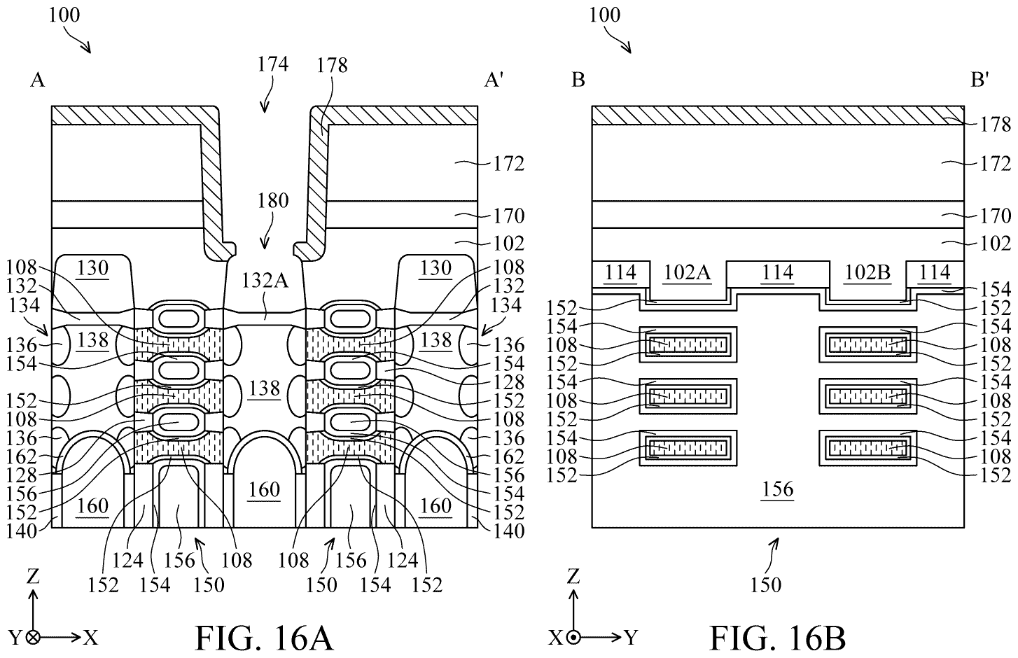

Referring to FIGS. 16A and 16B, the semiconductor material layer 130A is removed through the opening 174 to form an opening 180, so that the openings 174 and 180 collectively expose the bottom isolation layer 132 under the semiconductor material layer 130A, in accordance with some embodiments. It should be noted that, for the purpose of clarity and simplicity, the bottom isolation layer 132 exposed by the opening 180 is referred to as the bottom isolation layer 132A below. In some embodiments, a selective etching process is performed to remove the semiconductor material layer 130A through the opening 174. In some embodiments, the selective etching process is performed that selectively etches the semiconductor material layer 130A, with minimal etching (or substantially no etching) of the insulating layer 178, the bottom isolation layer 132A, the isolation structures 114, and the substrate 102. The selective etching processes of the semiconductor material layer 130A may be dry etching processes, wet etching processes, other suitable etching processes, or combinations thereof.

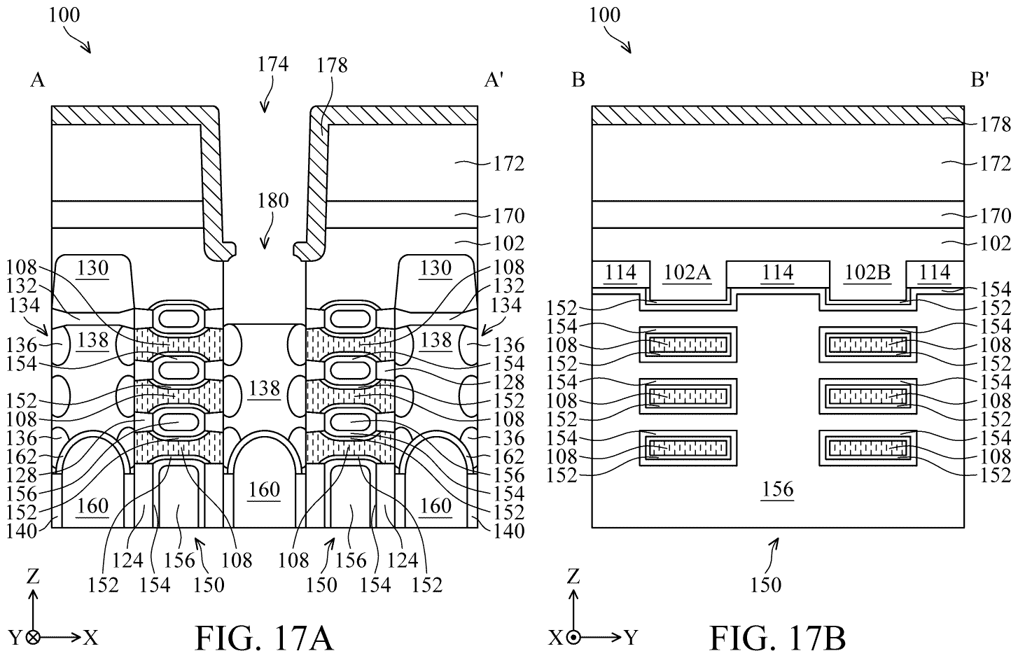

Referring to FIGS. 17A and 17B, the bottom isolation layer 132A is removed through the openings 174 and 180 to extend the opening 180, such that the openings 174 and 180 collectively expose the source/drain feature 134 below the bottom isolation layer 132A, in accordance with some embodiments. In some embodiments, the opening 180 is also slightly enlarged in the X-direction and the Y-direction during the removal of the bottom isolation layer 132A. In some embodiments, the topmost inner spacers 128 (the inner spacers 128 that are closest to the substrate 102) are also exposed by the opening 180.

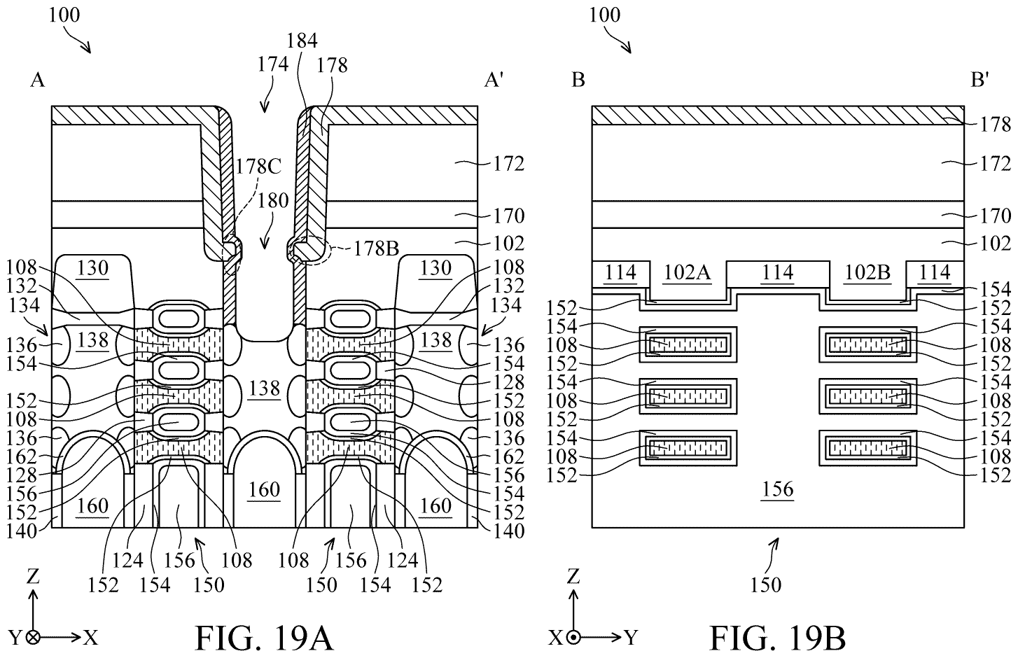

In some embodiments, a selective etching process is performed to remove the bottom isolation layer 132A through the opening 180 to extend the opening 180. In some embodiments, the selective etching process is performed that selectively etches the bottom isolation layer 132A, with minimal etching (or substantially no etching) of the insulating layer 178, the inner spacers 128, the gate spacers 124, the isolation structures 114, and the substrate 102. The selective etching processes of the bottom isolation layer 132A may be dry etching processes, wet etching processes, other suitable etching processes, or combinations thereof. In other embodiments, the bottom isolation layer 132A is removed at different fabrication stage. For example, the bottom isolation layer 132A may be removed together with the horizontal portions of the dielectric material layer 182 during the formation of the sidewall dielectric layer 184 (see FIGS. 19A and 19B).

In some embodiments, after removing the semiconductor material layer 130A and the bottom isolation layer 132A, the opening 180 is formed in the place previously occupied by the semiconductor material layer 130A and the bottom isolation layer 132A. Then, the source/drain feature 134 below the bottom isolation layer 132A is exposed by the openings 174 and 180. In some embodiments, the widths of the opening 174 are greater than the widths of the opening 180 in the X-direction and Y-direction.

By forming the semiconductor material layer 130 below the source/drain feature 134 (before flipping the workpiece 100) and removing the semiconductor material layer 130 by a selective etching process, the opening 180 and the source/drain contact 190 (see FIGS. 21A to 21C) that will be formed in the opening 180 may be formed by a self-aligned process. Which can keep the opening 180 and the source/drain contact formed in the opening 180 from contacting other conductive components. In this way, the entire space occupied by the semiconductor material layer 130 may be utilized effectively to form the source/drain contact. Therefore, the dimensions of the source/drain contact can be enlarged as much as possible to reduce the resistance, and the problem of short-circuits occurring with other conductive components can be avoided at the same time.

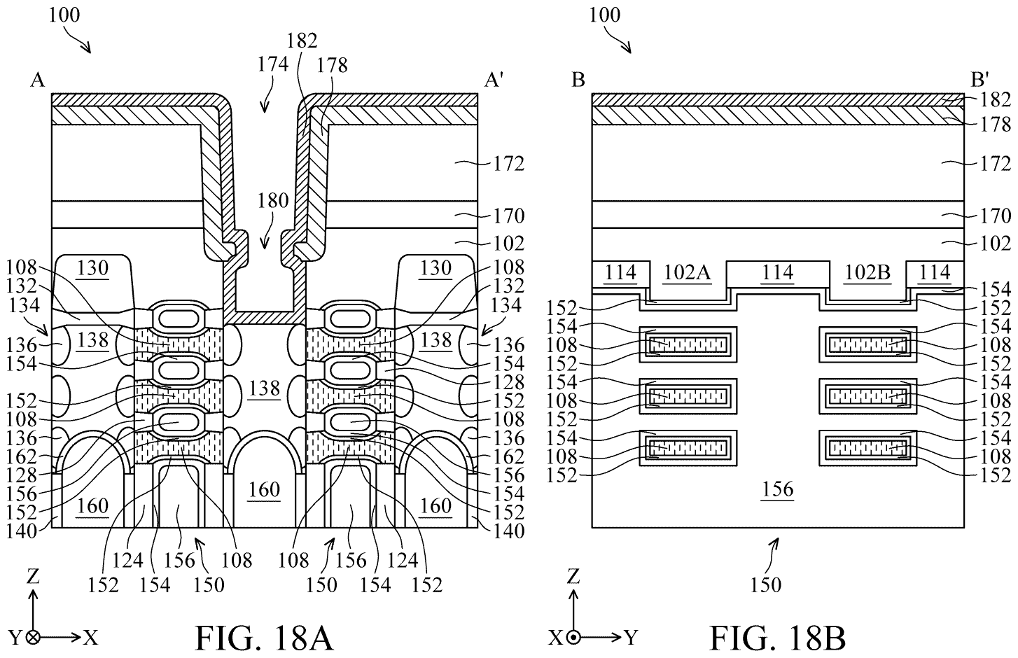

Referring to FIGS. 18A and 18B, the dielectric material layer 182 is formed in the openings 174 and 180 and on the source/drain feature 134 below the bottom isolation layer 132A, in accordance with some embodiments. More specifically, the dielectric material layer 182 is conformally formed on the insulating layer 178, the sidewall of the opening 180, and the top surface of the source/drain feature 134 exposed by the opening 180, wherein the insulating layer 178 is formed on the sidewall of the opening 174 and on the top surface of the hard mask layer 172. In some embodiments, the dielectric material layer 182 may include Si₃N₄, SiO₂, SiC, SiOC, SiON, SiCN, SiOCN, high-k dielectrics, other suitable materials, or combinations thereof. In some embodiments, the dielectric material layer 182 may be deposited by CVD, PVD, ALD, HDPCVD, MOCVD, RPCVD, PECVD, LPCVD, ALCVD, APCVD, other suitable methods, or combinations thereof.

Referring to FIGS. 19A and 19B, horizontal portions of the dielectric material layer 182 are removed to form the sidewall dielectric layer 184, in accordance with some embodiments. In some embodiments, an anisotropic etching process is performed to remove the horizontal portions of the dielectric material layer 182 to expose the source/drain feature 134 below the bottom isolation layer 132A, and the vertical portions of the dielectric material layer 182 are remained to constitute the sidewall dielectric layer 184, as shown in FIG. 19A. In some embodiments, the anisotropic etching process also recesses the first epitaxial layers 136 and the second epitaxial layers 138. For example, the topmost first epitaxial layers 136 (the first epitaxial layers 136 that are closest to the substrate 102) and the second epitaxial layers 138 are partially etched during the anisotropic etching process, and thus the opening 180 is extended into the source/drain feature 134. In some embodiments, the anisotropic etching process is a dry (e.g., plasma) etching process.

In some embodiments, after the anisotropic etching process, the sidewall dielectric layer 184 is formed on the insulating layer 178 formed on the sidewall of the opening 174 and is formed on the sidewall of the opening 180. In some embodiments, the sidewall dielectric layer 184 is in contact with the topmost inner spacers 128 (the inner spacers 128 that are closest to the substrate 102). In some embodiments, a first portion of the sidewall dielectric layer 184 formed on the protrusion portion 178B of the insulating layer 178 is thinner than the other portion of the sidewall dielectric layer 184.

As described above, in some embodiments, the bottom isolation layer 132A may be removed together with the horizontal portions of the dielectric material layer 182 during the formation of the sidewall dielectric layer 184. In these embodiments, after the formation of the sidewall dielectric layer 184, the lower portion of the sidewall dielectric layer 184 that is in contact with the source/drain feature 134 is formed from the bottom isolation layer 132A, and the upper portion of the sidewall dielectric layer 184 over the lower portion of the sidewall dielectric layer 184 is formed from the dielectric material layer 182.

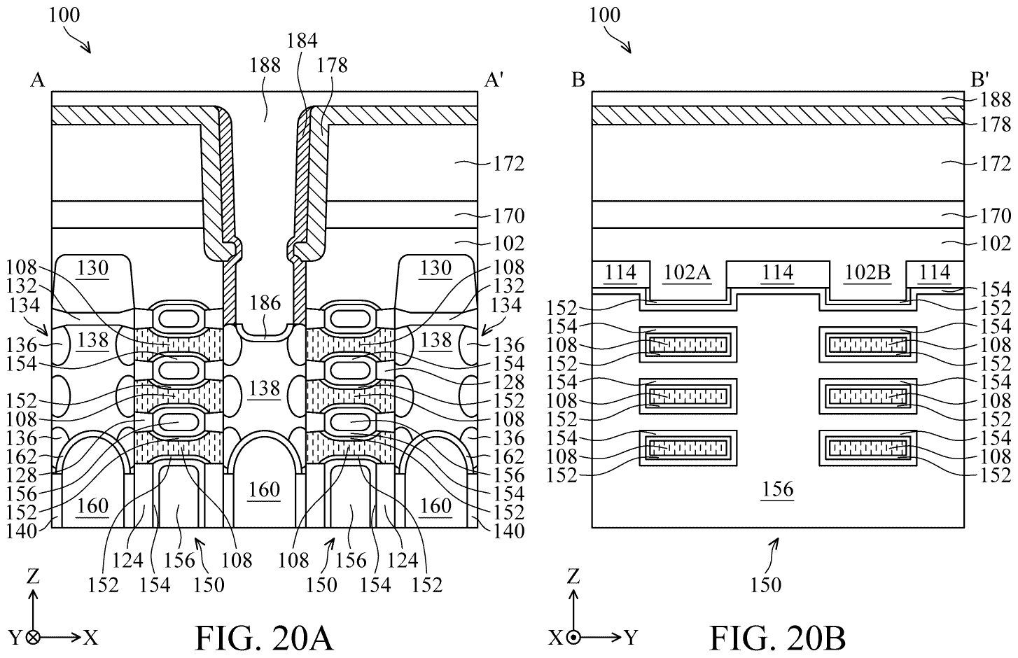

Referring to FIGS. 20A and 20B, a silicide layer 186 is formed on a top surface of the source/drain feature 134 exposed by the openings 174 and 180, in accordance with some embodiments. In some embodiments, the method and material used in forming the silicide layer 186 are the same as or similar to those of the silicide layers 162, and are not repeated herein.

Still referring to FIGS. 20A and 20B, a conductive material 188 is deposited on the backside of the workpiece 100 and in the openings 174 and 180, in accordance with some embodiments. In some embodiments, the conductive material 188 may include a conductive material such as Al, Cu, W, Co, Ti, Ta, Ru, Rh, Ir, Pt, Mo, TiN, TiAl, TiAlN, TaN, TaC, combinations of these, or the like, although any suitable material may be deposited using a deposition process such as sputtering, CVD, PVD, ALD, HDPCVD, MOCVD, RPCVD, PECVD, LPCVD, ALCVD, APCVD, FCVD, electroplating, electroless plating, or the like. However, any suitable materials and processes may be utilized to deposit the conductive material 188. In some embodiments, the conductive material 188 may include a single conductive material layer or multiple conductive layers.

Referring to FIGS. 21A to 21C, a planarization process (e.g., a CMP process and/or other planarization processes) is performed on the backside of the workpiece 100 until the top surface of the hard mask layer 170 is exposed, so as to form a source/drain contact 190, in accordance with some embodiments. In some embodiments, the hard mask layer 172 and the portions of the insulating layer 178, the sidewall dielectric layer 184, and the conductive material 188 over the hard mask layer 172 are removed by the planarization process, and the remaining portions of the insulating layer 178, the sidewall dielectric layer 184, and the conductive material 188 form the source/drain contact 190. Since the source/drain contact 190 is formed on the backside of the workpiece 100, the source/drain contact 190 may also be referred to as the backside source/drain contact.

In some embodiments, the source/drain contact 190 includes a first portion 190A formed in the opening 174 and a second portion 190B formed in the opening 180. In some embodiments, the first portion 190A is constituted by the insulating layer 178, the upper portion of the sidewall dielectric layer 184 surrounded by the insulating layer 178, and upper portion of the conductive material 188 surrounded by the insulating layer 178 and the upper portion of the sidewall dielectric layer 184, as shown in FIGS. 21A and 21C. In some embodiments, the second portion 190B is below the first portion 190A, in contact with the source/drain feature 134, and constituted by the lower portion of the sidewall dielectric layer 184 formed on the sidewall of the opening 180 and the lower portion of the conductive material 188 surrounded by the lower portion of the sidewall dielectric layer 184, as shown in FIGS. 21A and 21C.

In some embodiments, the widths of the first portion 190A are greater than the widths of the second portion 190B in the X-direction and Y-direction. In some embodiments, since the first portion 190A is wider than the second portion 190B and the insulating layer 178 is formed on the periphery of the first portion 190A, a portion of the substrate 102 is vertically sandwiched between the insulating layer 178 and the second semiconductor layers 108 in the Z-direction, as shown in FIG. 21A. In some embodiments, a portion of the substrate 102 is vertically sandwiched between the insulating layer 178 and the inner spacers 128 in the Z-direction. In further embodiments, portions of the isolation structures 114 are vertically sandwiched between the insulating layer 178 and the gate spacers 124 in the Z-direction, as shown in FIG. 21C.

As described above, the second portion 190B of the source/drain contact 190 (i.e., backside source/drain contact) is formed in the opening 180, and the opening 180 is formed in the place previously occupied by the semiconductor material layer 130A. Since the semiconductor material layer 130A can be removed in a manner of selective etching process, the space occupied by the semiconductor material layer 130A can be fully utilized to form the second portion 190B of the source/drain contact 190, so as to reduce the resistance of the source/drain contact 190.

Further, since the semiconductor material layer 130A is removed by the selective etching process, it prevents the opening 180 from exposing other conductive components (e.g., the gate structures 150). Therefore, it keeps the second portion 190B of the source/drain contact 190 from contacting the other conductive components, so as to avoid causing a short-circuit between the source/drain contact 190 and other conductive components. Moreover, since the opening 180 is formed by selectively removing the semiconductor material layer 130A instead of photolithography process, even if the source/drain feature 134 is small, the source/drain contact 190 formed in the opening 180 can still be reliably connected to the source/drain feature 134.

Furthermore, since the opening 174 is formed to expose the semiconductor material layer 130A, the opening 174 can be formed greater while avoiding contact with other conductive components. Therefore, the first portion 190A of the (backside) source/drain contact 190 formed in the opening 174 may have greater cross sectional area, so as to reduce the resistance of the source/drain contact 190.

On the other hand, as described above, the insulating layer 178 is formed on the periphery of the first portion 190A of the (backside) source/drain contact 190. That is, the insulating layer 178 covers the corner of the first portion 190A, and separates the conductive material 188 from the other components. In this way, the insulating layer 178 can prevent the source/drain contact 190 from the leakage, such as the leakage between the source/drain contact 190 and the gate structures 150. For example, in the case of omitting the insulating layer 178, the sidewall dielectric layer on the corner of the first portion 190A may disappear or may be too thin to separate the conductive material from the substrate 102 due to the removal of the horizontal portions of the sidewall dielectric layer. In this case, it is likely that a leakage will occur between the corner of the first portion 190A and the gate structures 150 through the substrate 102. However, by forming the insulating layer 178, the corner of the first portion 190A can be protected and the route of the leakage can be blocked by the insulating layer 178. Therefore, the insulating layer 178 can prevent the source/drain contact 190 from the leakage.

Moreover, when the overlay shift is occurred during the formation of the first opening that exposes the semiconductor material layer, the first opening greater than the semiconductor material layer can still expose the semiconductor material layer, and thus the requirement of the overlay control can be mitigated. FIG. 22 is an X-Z cross-sectional view of a workpiece 200 at a fabrication stage along a line A-A′ of FIG. 4, in accordance with some alternative embodiments. The workpiece 200 shown in FIG. 22 may be similar to the workpiece 100 shown in FIGS. 13A and 13B, except the opening 174 shown in FIGS. 13A and 13B is replaced by an opening 274 shown in FIG. 22.

Referring to FIG. 22, the opening 274 is formed to expose the semiconductor material layer 130A, in accordance with some embodiments. In FIG. 22, an overlay shift is occurred during the formation of the opening 274, and thus the semiconductor material layer 130A exposed by the opening 274 is not located at the middle of the bottom of the opening 274 in the X-direction (and, in some embodiments, in the Y-direction). However, similar to the opening 174, the opening 274 has widths greater than the semiconductor material layer 130A in the X-direction and/or Y-direction. Therefore, although the overlay shift is occurred, the opening 274 can still fully expose the semiconductor material layer 130A. Then, the opening 180 replacing the place of the semiconductor material layer 130A can be formed smoothly. Afterwards, the fabrication stages shown in FIGS. 14A to 21C may be performed to complete the fabrication of the workpiece 200. In this way, since the process can be performed smoothly when an overlay shift is occurred, the requirement of the overlay control can be mitigated, so as to reduce the time and cost of the fabrication process.

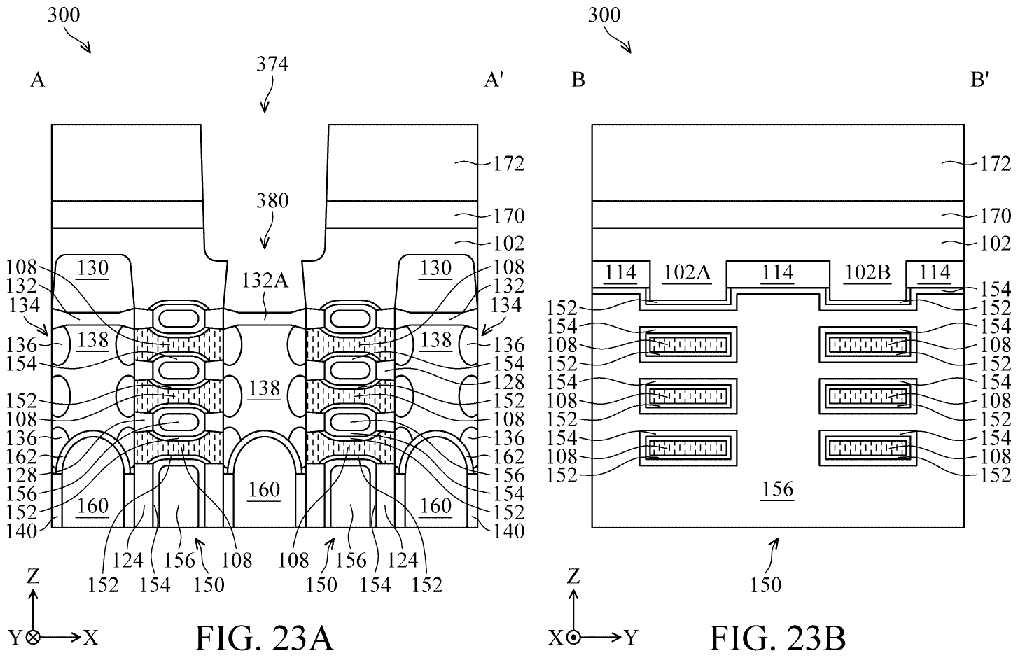

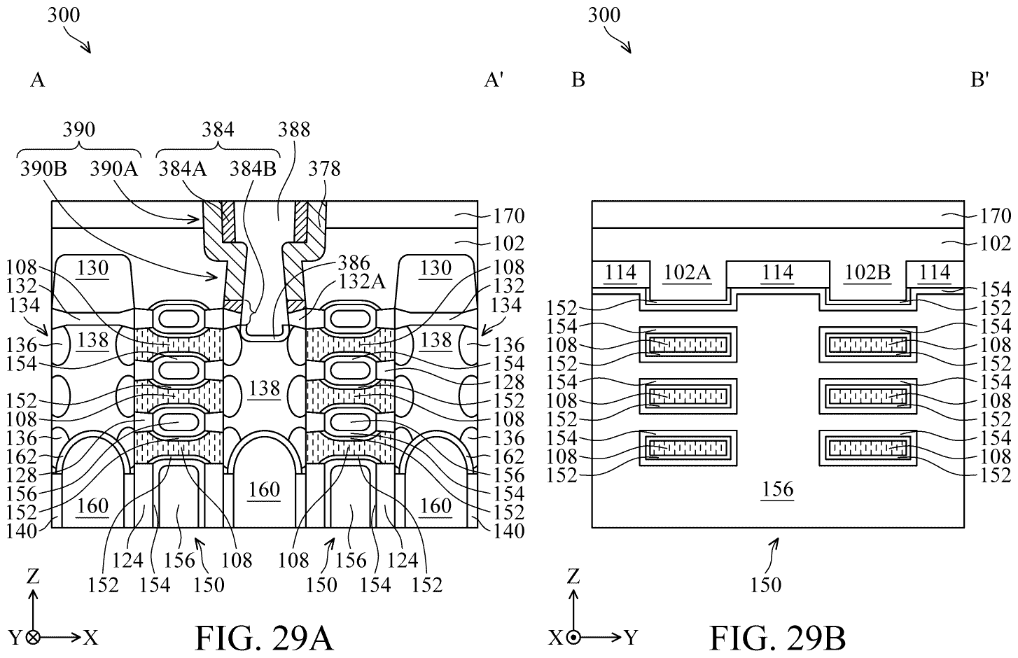

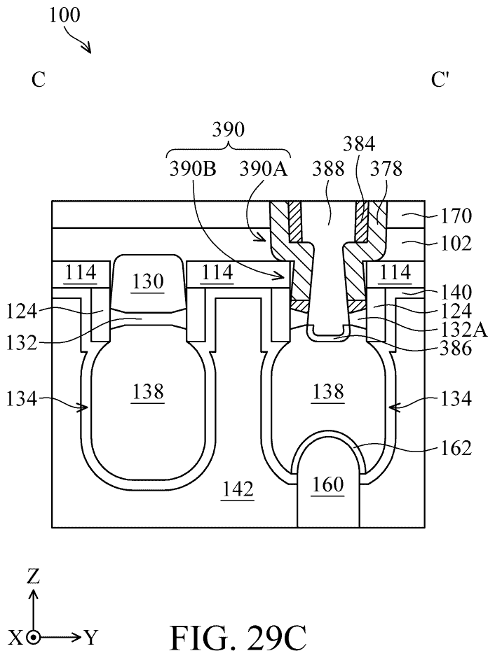

FIGS. 23A, 24A, 25A, 26A, 27A, 28A, and 29A are X-Z cross-sectional views of the workpiece 300 at various fabrication stages along line A-A′ of FIG. 4, in accordance with some alternative embodiments. FIGS. 23B, 24B, 25B, 26B, 27B, 28B, and 29B are Y-Z cross-sectional views of the workpiece 300 at various fabrication stages along line B-B′ of FIG. 4, in accordance with some alternative embodiments. FIG. 29C is a Y-Z cross-sectional view of the workpiece 300 at a fabrication stage along line C-C′ of FIG. 4, in accordance with some alternative embodiments. Since the workpiece 300 will be fabricated into a semiconductor structure 300 upon conclusion of the fabrication processes, the workpiece 300 may be referred to as the semiconductor structure 300 as the context requires.

Referring to FIGS. 23A and 23B, the fabrication stage shown in FIGS. 23A and 23B follows the fabrication stage shown in FIGS. 13A and 13B. It should be noted that, for the purpose of clarity and simplicity, the opening 174 shown in FIGS. 13A and 13B is referred to as the opening 374 in FIGS. 23A and 23B and below. In FIGS. 23A and 23B, the semiconductor material layer 130A is removed through the opening 374 to form the opening 380, so that the openings 374 and 380 collectively expose the bottom isolation layer 132A, in accordance with some embodiments.

In some embodiments, a selective etching process is performed to remove the semiconductor material layer 130A through the opening 374. In some embodiments, the selective etching process is performed that selectively etches the semiconductor material layer 130A, with minimal etching (or substantially no etching) of the bottom isolation layer 132A, the isolation structures 114, and the substrate 102. The selective etching processes of the semiconductor material layer 130A may be dry etching processes, wet etching processes, other suitable etching processes, or combinations thereof. In these embodiments, the opening 380 is formed in the place previously occupied by the semiconductor material layer 130A.

In other embodiments, after forming the opening 380, an additional selective etching process is performed to remove the bottom isolation layer 132A, so as to extend the opening 380 and expose the source/drain feature 134 below the bottom isolation layer 132A. The additional selective etching process is the same as or similar to the fabrication stage described with reference to FIGS. 17A and 17B, and is not repeated herein. In these embodiments, the opening 380 is formed in the place previously occupied by the semiconductor material layer 130A and the bottom isolation layer 132A.

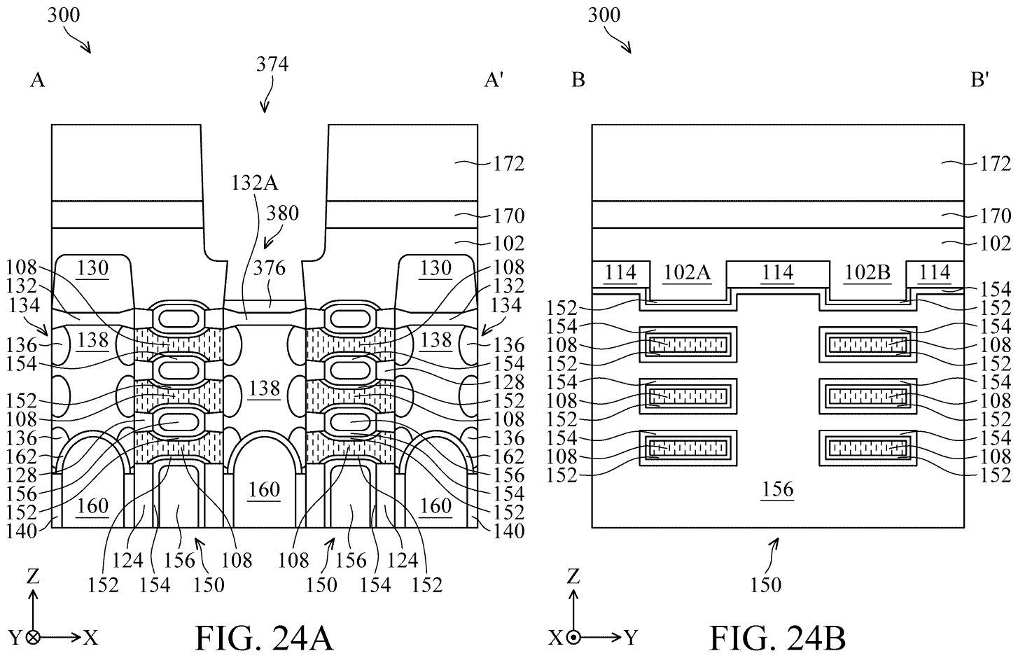

Referring to FIGS. 24A and 24B, a carbon layer 376 is formed at the bottom of the opening 380 and over the source/drain feature 134 below the bottom isolation layer 132A, in accordance with some embodiments. In some embodiments, the carbon layer 376 is an amorphous carbon layer. In some embodiments, the carbon layer 376 is formed at the bottom of the opening 380 and on the bottom isolation layer 132A, as shown in FIG. 24A. In the embodiments where the bottom isolation layer 132A has been removed before forming the carbon layer 376, the carbon layer 376 is formed at the bottom of the opening 380 and on the exposed surface of the source/drain feature 134.

In some embodiments, the carbon layer 376 is formed by a deposition process, such as CVD, PVD, ALD, HDPCVD, MOCVD, RPCVD, PECVD, LPCVD, ALCVD, APCVD, other suitable methods, or combinations thereof. In some embodiments, the parameters of the deposition process are configured to cause the carbon layer 376 to be deposited in more of a bottom-up manner than a lateral manner. In this way, the carbon layer 376 may be formed as a horizontal layer without a vertical portion formed on the sidewall of the opening 374 and 380. In some embodiments, the formation of the carbon layer 376 further includes an etching process, the etching process is combined with the deposition process to control the shape of the carbon layer 376.

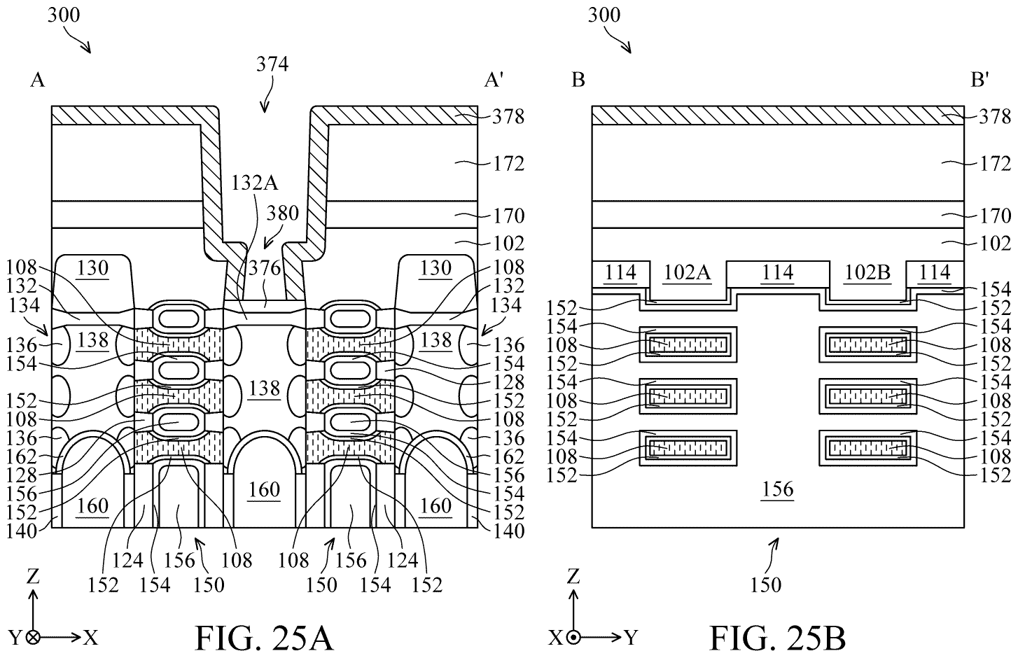

Referring to FIGS. 25A and 25B, an insulating layer 378 is formed on the hard mask layer 172 and in the openings 374 and 380, in accordance with some embodiments. In some embodiments, the insulating layer 378 is conformally formed on the top surface of the hard mask layer 172, the sidewall of the opening 374, and the sidewall of the opening 380. More specifically, for the opening 380, the insulating layer 378 is formed on a portion of the sidewall that is not covered by the carbon layer 376.

In some embodiments, the carbon layer 376 may suppress the deposition or growth of the material of the insulating layer 378 on the carbon layer 376. Therefore, the insulating layer 378 is formed on the sidewalls of the openings 374 and 380, without forming on the surface of the carbon layer 376. That is, the insulating layer 378 has vertical portion formed on the sidewalls of the openings 374 and 380, and is not formed on the surface of the carbon layer 376, as shown in FIG. 25A. After the formation of the insulating layer 378, the carbon layer 376 is still exposed by the opening 380. In some embodiments, the method and material used in forming the insulating layer 378 are the same as or similar to those of the insulating layer 178, and are not repeated herein.

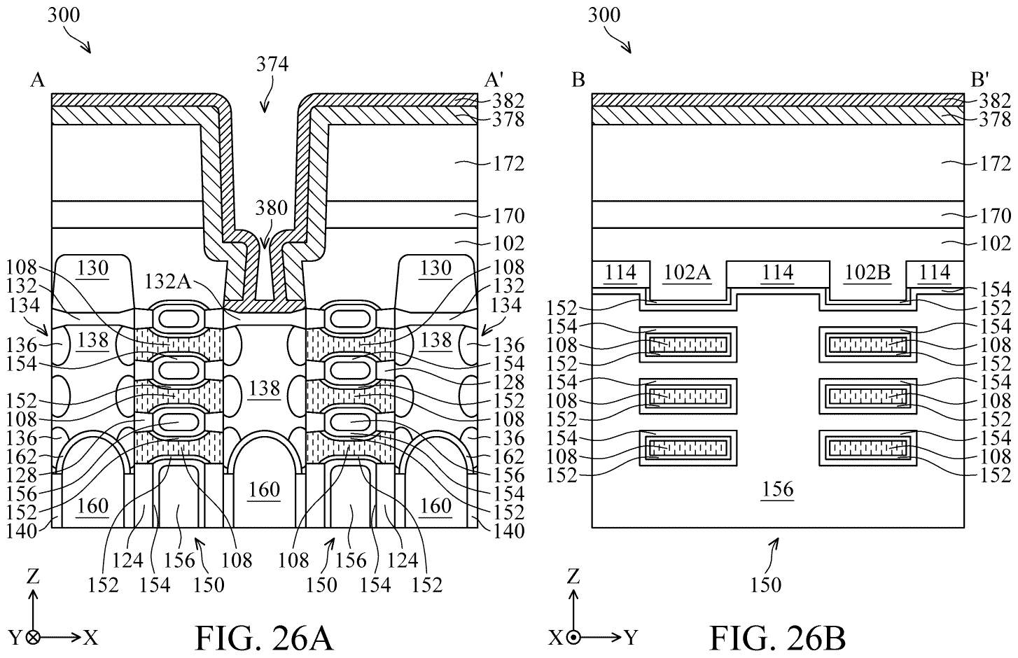

Referring to FIGS. 26A and 26B, the carbon layer 376 is removed through the opening 374 and the opening 380, such that the bottom isolation layer 132A is exposed, in accordance with some embodiments. In the embodiments where the bottom isolation layer 132A has been removed before forming the carbon layer 376, the source/drain feature 134 below the bottom isolation layer 132A is exposed after removing the carbon layer 376. In these embodiments, the topmost inner spacers 128 (the inner spacers 128 that are closest to the substrate 102) are also exposed by the opening 380.

In some embodiments, a selective etching process is performed to remove the carbon layer 376 through the opening 380. In some embodiments, the selective etching process is performed that selectively etches the carbon layer 376, with minimal etching (or substantially no etching) of the insulating layer 378, the bottom isolation layer 132A, the source/drain feature 134, the inner spacers 128, the gate spacers 124, the isolation structures 114, and the substrate 102. The selective etching processes of the carbon layer 376 may be dry etching processes, wet etching processes, other suitable etching processes, or combinations thereof. In other embodiments, the bottom isolation layer 132A is removed after the removal of the carbon layer 376. For example, another selective etching process is performed after removing the carbon layer 376 to remove the bottom isolation layer 132A, so as to extend the opening 380 and expose the source/drain feature 134.

Still referring to FIGS. 26A and 26B, a dielectric material layer 382 is formed in the openings 374 and 380 and on the bottom isolation layer 132A, in accordance with some embodiments. More specifically, the dielectric material layer 382 is conformally formed on the insulating layer 378 formed on the sidewalls of the openings 374 and 380 and on the top surface of the hard mask layer 172, on the top surface of the bottom isolation layer 132A exposed by the opening 380, and on a portion of the sidewall of the opening 380 that is exposed after removing the carbon layer 376. In the embodiments where the bottom isolation layer 132A has been removed before forming the dielectric material layer 382, instead of the top surface of the bottom isolation layer 132A, the dielectric material layer 382 is formed on the surface of the inner spacers 128 and the source/drain feature 134 exposed by the opening 380. In some embodiments, the method and material used in forming the dielectric material layer 382 are the same as or similar to those of the dielectric material layer 182, and are not repeated herein.

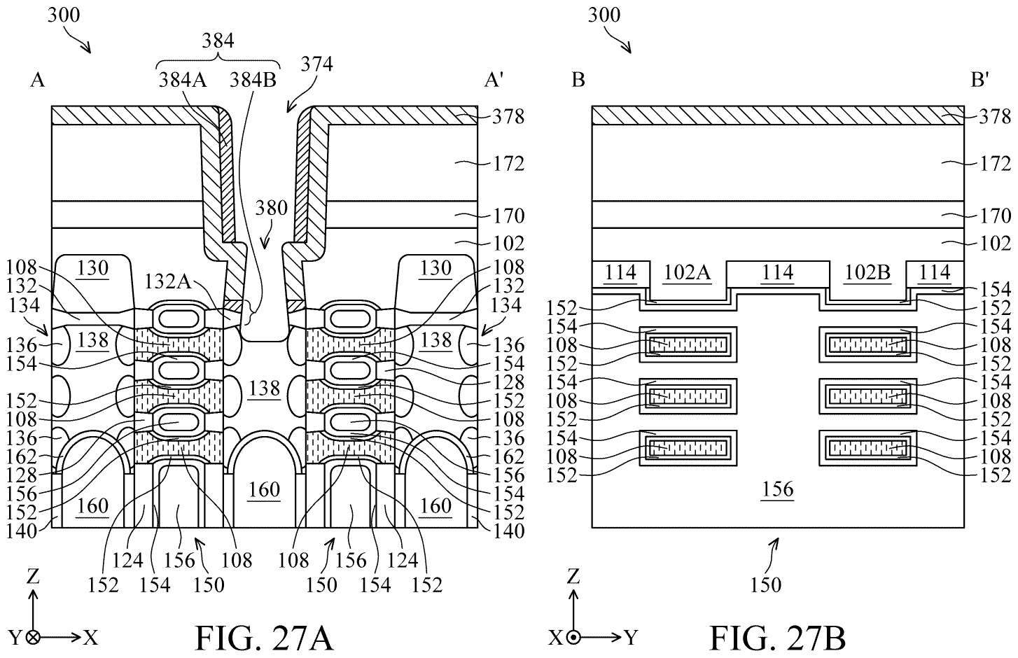

Referring to FIGS. 27A and 27B, horizontal portions of the dielectric material layer 382 are removed to form the sidewall dielectric layer 384, in accordance with some embodiments. In some embodiments, an anisotropic etching process is performed to remove the horizontal portions of the dielectric material layer 382, and the vertical portions of the dielectric material layer 382 are remained to constitute the sidewall dielectric layer 384, as shown in FIG. 27A. In some embodiments, the anisotropic etching process further partially removes the bottom isolation layer 132A to expose the source/drain feature 134, and then recesses the first epitaxial layers 136 and the second epitaxial layers 138. For example, the topmost first epitaxial layers 136 (the first epitaxial layers 136 that are closest to the substrate 102) and the second epitaxial layers 138 are partially etched during the anisotropic etching process, and thus the opening 380 is extended into the source/drain feature 134. In some embodiments, the anisotropic etching process is a dry (e.g., plasma) etching process.

In some embodiments, after the anisotropic etching process, the sidewall dielectric layer 384 is formed to include a first portion 384A and a second portion 384B that is separated from and below the first portion 384A. In some embodiments, the first portion 384A is formed in the opening 374, and is formed on the upper portion of the insulating layer 378 that is formed on the sidewall of the opening 374. In some embodiments, the second portion 384B is formed in the opening 380, and is formed below the insulating layer 378, on the sidewalls of the topmost inner spacers 128, and on a lower portion of the sidewall of the opening 380 that is not covered by the insulating layer 378. In some embodiments, the surface of the lower portion of the insulating layer 378 formed on the sidewall of the opening 380 is free of the sidewall dielectric layer 384. In some embodiments, the upper portion of the sidewall of the opening 380 is covered by the lower portion of the insulating layer 378, and the lower portion of the sidewall of the opening 380 is covered by the second portion 384B.

In some embodiments, the second portion 384B of the sidewall dielectric layer 384 includes the materials from the dielectric material layer 382 and the bottom isolation layer 132A. For example, the second portion 384B includes an upper portion constituted by the material of the dielectric material layer 382 and a lower portion constituted by the material of the bottom isolation layer 132A, as shown in FIG. 27A. In the embodiments where the bottom isolation layer 132A has been removed before forming the dielectric material layer 382, the second portion 384B is constituted by the material of the dielectric material layer 382.

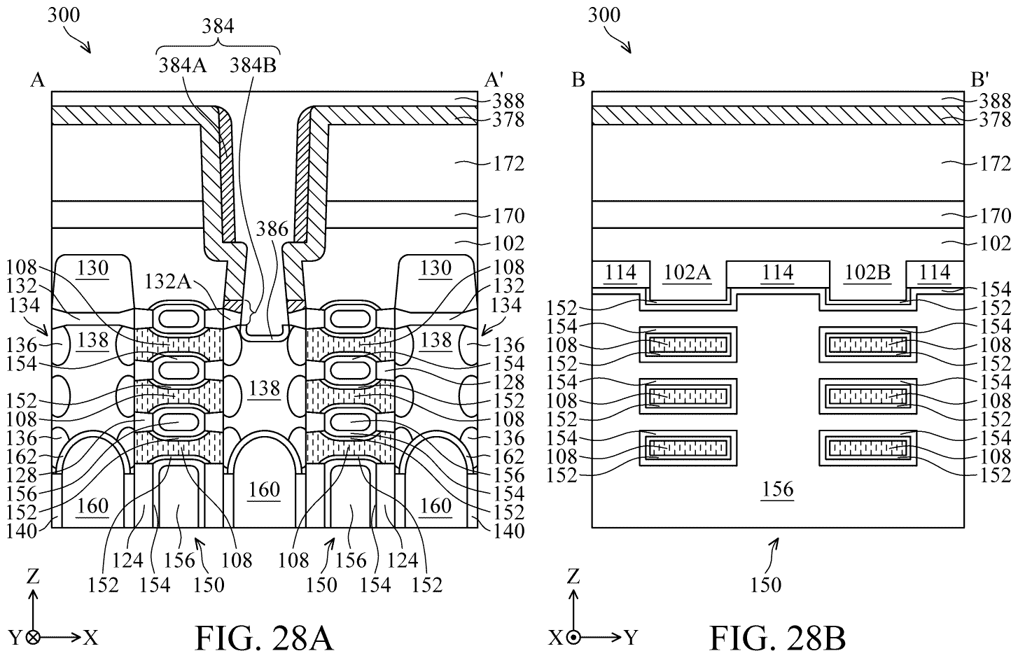

Referring to FIGS. 28A and 28B, a silicide layer 386 is formed on a top surface of the source/drain feature 134 exposed by the openings 374 and 380, in accordance with some embodiments. In some embodiments, the method and material used in forming the silicide layer 386 are the same as or similar to those of the silicide layers 162, and are not repeated herein.

Still referring to FIGS. 28A and 28B, a conductive material 388 is deposited on the backside of the workpiece 300 and in the openings 374 and 380, in accordance with some embodiments. In some embodiments, the method and material used in forming the conductive material 388 are the same as or similar to those of the conductive material 188, and are not repeated herein. In some embodiments, the conductive material 388 may include a single conductive material layer or multiple conductive layers.

Referring to FIGS. 29A to 29C, a planarization process (e.g., a CMP process and/or other planarization processes) is performed on the backside of the workpiece 300 until the top surface of the hard mask layer 170 is exposed, so as to form a source/drain contact 390, in accordance with some embodiments. In some embodiments, the hard mask layer 172 and the portions of the insulating layer 378, the sidewall dielectric layer 384, and the conductive material 388 over the hard mask layer 172 are removed by the planarization process, and the remaining portions of the insulating layer 378, the sidewall dielectric layer 384, and the conductive material 388 form the source/drain contact 390. Since the source/drain contact 390 is formed on the backside of the workpiece 300, the source/drain contact 390 may also be referred to as the backside source/drain contact.

In some embodiments, the source/drain contact 390 includes a first portion 390A formed in the opening 374 and a second portion 390B formed in the opening 380. In some embodiments, the first portion 390A is constituted by the upper portion of the insulating layer 378, the first portion 384A of the sidewall dielectric layer 384 surrounded by the upper portion of the insulating layer 378, and upper portion of the conductive material 388 surrounded by the upper portion of the insulating layer 378 and the first portion 384A of the sidewall dielectric layer 384, as shown in FIGS. 29A and 29C. In some embodiments, the second portion 390B is below the first portion 390A, in contact with the source/drain feature 134, and constituted by the lower portion of the insulating layer 378, the second portion 384B of the sidewall dielectric layer 384, and the lower portion of the conductive material 388 surrounded by the second portion 384B and the lower portion of the insulating layer 378, as shown in FIGS. 29A and 29C.

In some embodiments, the widths of the first portion 390A are greater than the widths of the second portion 390B in the X-direction and Y-direction. In some embodiments, since the first portion 390A is wider than the second portion 390B and the upper portion of the insulating layer 378 is formed on the periphery of the first portion 390A, a portion of the substrate 102 is vertically sandwiched between the upper portion of the insulating layer 378 and the second semiconductor layers 108 in the Z-direction, as shown in FIG. 29A. In some embodiments, a portion of the substrate 102 is vertically sandwiched between the upper portion of the insulating layer 378 and the inner spacers 128 in the Z-direction. In further embodiments, portions of the isolation structures 114 are vertically sandwiched between the upper portion of the insulating layer 378 and the gate spacers 124 in the Z-direction.

As described above, the second portion 390B of the (backside) source/drain contact 390 is formed in the opening 380, and the opening 380 is formed in the place previously occupied by the semiconductor material layer 130A. Furthermore, the opening 374 is greater than the opening 380, and thus the first portion 390A formed in the opening 374 is greater than the second portion 390B formed in the opening 380. Therefore, similar to the source/drain contact 190, the resistance of the source/drain contact 390 can be reduced, the short-circuit between the source/drain contact 390 and other conductive components can be avoided, and even if the source/drain feature 134 is small, the source/drain contact 390 can still be reliably connected to the source/drain feature 134.

On the other hand, as described above, the insulating layer 378 is formed on the periphery of the first portion 390A of the (backside) source/drain contact 390. That is, the insulating layer 378 covers the corner of the first portion 390A, and separates the conductive material 388 from the other components. Therefore, similar to the source/drain contact 190, the insulating layer 378 can prevent the source/drain contact 390 from the leakage, such as the leakage between the source/drain contact 390 and the gate structures 150. Moreover, since the opening 374 is greater than the opening 380, as described with reference to FIG. 22, the fabrication process shown in FIGS. 23A to 29C can be performed smoothly when an overlay shift is occurred. Therefore, the requirement of the overlay control can be mitigated, so as to reduce the time and cost of the fabrication process.

The embodiments disclosed herein relate to semiconductor structures and their forming methods, and more particularly to methods and semiconductor structures that include forming semiconductor material layers (e.g., SiGe layers) below the S/D features. The backside S/D contact may be formed in a first opening and a second opening below the first opening and formed by selectively removing the semiconductor material layer. The selective removal can fully utilized the space occupied by the semiconductor material layer to form the backside S/D contact, so as to reduce the resistance of the backside S/D contact and connect to the small source/drain feature reliably. It also keeps the backside S/D contact from contacting the gate to avoid causing a short-circuit. Moreover, the insulating layer formed on the periphery of the backside S/D contact can prevent the backside S/D contact from the leakage. Furthermore, the first opening is greater than the second opening, so that the resistance of the backside S/D contact can be reduced and the requirement of the overlay control can be mitigated.

In one exemplary aspect, the present disclosure is directed to a method of forming a semiconductor structure. The method includes forming a fin structure including first semiconductor layers and second semiconductor layers alternately stacked over a substrate; forming a first source/drain trench and a second source/drain trench in the fin structure; and forming a first semiconductor material layer and a second semiconductor material layer in the first source/drain trench and the second source/drain trench, respectively. The method further includes forming a first source/drain feature and a second source/drain feature over the first semiconductor material layer and the second semiconductor material layer in the first source/drain trench and the second source/drain trench, respectively; removing the first semiconductor layers; and forming a gate structure to wrap around the second semiconductor layers. The method further includes flipping the semiconductor structure; forming a hard mask layer on a backside of the substrate; and etching the hard mask layer and the substrate to form a first opening that exposes the first semiconductor material layer. A first width of the first opening is greater than a second width of the first semiconductor material layer. The method further includes forming an insulating layer on a sidewall of the first opening; removing the first semiconductor material layer to form a second opening that exposes the first source/drain feature; and depositing a conductive material in the first opening and the second opening to form a first source/drain contact.

In another exemplary aspect, the present disclosure is directed to a method of forming a semiconductor structure. The method includes forming a fin structure extending in a first horizontal direction over a substrate and including first semiconductor layers and second semiconductor layers alternately stacked in a vertical direction; forming a dummy gate structure over the fin structure and extending in a second horizontal direction; and forming a first semiconductor material layer and a second semiconductor material layer on opposite sides of the dummy gate structure in the first horizontal direction. The method further includes forming a first isolation layer and a second isolation layer on the first semiconductor material layer and the second semiconductor material layer, respectively; and forming a first source/drain feature and a second source/drain feature on the first isolation layer and the second isolation layer, respectively. The first source/drain feature and the second source/drain feature are attached to opposite sides of the second semiconductor layers. The method further includes flipping the semiconductor structure; forming a first hard mask layer on a backside of the substrate and a second hard mask layer on the first hard mask layer; and etching the second hard mask layer, the first hard mask layer, and the substrate to form a first opening that exposes the first semiconductor material layer. The widths of the first opening are greater than the widths of the first semiconductor material layer in the first horizontal direction and the second horizontal direction. The method further includes forming an insulating layer on a first sidewall of the first opening; removing the first semiconductor material layer to form a second opening that exposes the first isolation layer; removing the first isolation layer to extend the second opening; and depositing a conductive material in the first opening and the second opening to form a first source/drain contact.

In yet another exemplary aspect, the present disclosure is directed to a semiconductor structure. The semiconductor structure includes a substrate; nanostructures below the substrate; a gate structure wrapped around each of the nanostructures; a first source/drain feature and a second source/drain feature, attached to opposite sides of the nanostructures in a first horizontal direction; and a hard mask layer over the substrate. The nanostructures are spaced apart from each other in a vertical direction. The semiconductor structure further includes a source/drain contact extending through the hard mask layer and the substrate and in contact with the first source/drain feature. The source/drain contact includes a first portion in contact with the first source/drain feature and a second portion on the first portion. The widths of the second portion are greater than the widths of the first portion in the first horizontal direction and a second horizontal direction, wherein the second horizontal direction is perpendicular to the first horizontal direction. The second portion of the source/drain contact includes a second conductive portion and a second insulating layer surrounding the second conductive portion. A portion of the substrate is vertically sandwiched between the second insulating layer and the nanostructures.

In yet another exemplary aspect, the present disclosure is directed to a method of forming a semiconductor structure. The method includes forming a fin structure including first semiconductor layers and second semiconductor layers alternately stacked over a substrate; forming a first source/drain trench and a second source/drain trench in the fin structure; partially removing the first semiconductor layers to form inner spacer recesses; and forming inner spacers in the inner spacer recesses. The method further includes forming a first semiconductor material layer and a second semiconductor material layer in the first source/drain trench and the second source/drain trench, respectively; and forming a first source/drain feature and a second source/drain feature over the first semiconductor material layer and the second semiconductor material layer, respectively. The method further includes flipping the semiconductor structure; forming a hard mask layer on a backside of the substrate; and etching the hard mask layer and the substrate to form a first opening that exposes the first semiconductor material layer. The method further includes forming an insulating layer on a sidewall of the first opening; removing the first semiconductor material layer to form a second opening; and depositing a conductive material in the first opening and the second opening to form a first source/drain contact.

In some embodiments, the method further includes before forming the insulating layer, introducing an inhibitor to the first semiconductor material layer through the first opening; and after forming the insulating layer, removing the inhibitor from the first opening. The first semiconductor material layer is removed after removing the inhibitor.

In some embodiments, the method further includes forming a first isolation layer on the first semiconductor material layer. The first isolation layer is between the first semiconductor material layer and the first source/drain feature. After removing the first semiconductor material layer, the first isolation layer is exposed by the second opening.

In some embodiments, the method further includes removing the first isolation layer to extend the second opening, so as to expose the first source/drain feature; forming a carbon layer at a bottom of the second opening and on the first source/drain feature, wherein the insulating layer is formed after forming the carbon layer, and wherein the insulating layer is formed on the sidewall of the first opening and a sidewall of the second opening; and after forming the insulating layer, removing the carbon layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor structure, comprising:
forming a fin structure over a substrate, wherein the fin structure comprises first semiconductor layers and second semiconductor layers alternately stacked;
forming a first source/drain trench and a second source/drain trench in the fin structure;
forming a first semiconductor material layer and a second semiconductor material layer in the first source/drain trench and the second source/drain trench, respectively;
forming a first source/drain feature and a second source/drain feature over the first semiconductor material layer and the second semiconductor material layer in the first source/drain trench and the second source/drain trench, respectively;
removing the first semiconductor layers;
forming a gate structure to wrap around the second semiconductor layers;
flipping the semiconductor structure;
forming a hard mask layer on a backside of the substrate;
etching the hard mask layer and the substrate to form a first opening that exposes the first semiconductor material layer, wherein a first width of the first opening is greater than a second width of the first semiconductor material layer;
forming an insulating layer on a sidewall of the first opening;
removing the first semiconductor material layer to form a second opening that exposes the first source/drain feature; and
depositing a conductive material in the first opening and the second opening to form a first source/drain contact.

2. The method of claim 1, further comprising:
before forming the insulating layer, introducing an inhibitor to the first semiconductor material layer through the first opening; and
after forming the insulating layer, removing the inhibitor from the first opening,
wherein the first semiconductor material layer is removed after removing the inhibitor.

3. The method of claim 1, further comprising:
conformally depositing a dielectric material layer in the first opening and the second opening; and
removing horizontal portions of the dielectric material layer to form a sidewall dielectric layer on sidewalls of the insulating layer and the second opening.

4. The method of claim 3,
wherein the insulating layer comprises a protrusion at a bottom of the first opening, and
wherein a first portion of the sidewall dielectric layer formed on the protrusion of the insulating layer is thinner than a second portion of the sidewall dielectric layer.

5. The method of claim 1, further comprising:
before depositing the conductive material, forming a silicide layer on a surface of the first source/drain feature exposed by the first opening and the second opening.

6. The method of claim 1, further comprising:
after removing the first semiconductor material layer, forming a carbon layer at a bottom of the second opening and over the first source/drain feature, wherein the insulating layer is formed after forming the carbon layer, and wherein the insulating layer is formed on the sidewall of the first opening and a sidewall of the second opening; and
after forming the insulating layer, removing the carbon layer.

7. The method of claim 1, further comprising:
partially removing the first semiconductor layers to form inner spacer recesses; and
forming inner spacers in the inner spacer recesses,
wherein the first opening and the inner spacers vertically overlap.

8. The method of claim 1, further comprising:
before flipping the semiconductor structure, forming an interlayer dielectric (ILD) layer over the first source/drain feature and the second source/drain feature;
etching the ILD layer to form a third opening that exposes the second source/drain feature; and
forming a second source/drain contact in the third opening.

9. A method of forming a semiconductor structure, comprising:
forming a fin structure extending in a first horizontal direction over a substrate,
wherein the fin structure comprises first semiconductor layers and second semiconductor layers alternately stacked in a vertical direction;
forming a dummy gate structure over the fin structure and extending in a second horizontal direction;
forming a first semiconductor material layer and a second semiconductor material layer on opposite sides of the dummy gate structure in the first horizontal direction;
forming a first isolation layer and a second isolation layer on the first semiconductor material layer and the second semiconductor material layer, respectively;
forming a first source/drain feature and a second source/drain feature on the first isolation layer and the second isolation layer, respectively, wherein the first source/drain feature and the second source/drain feature are attached to opposite sides of the second semiconductor layers;
flipping the semiconductor structure;
forming a first hard mask layer on a backside of the substrate and a second hard mask layer on the first hard mask layer;
etching the second hard mask layer, the first hard mask layer, and the substrate to form a first opening that exposes the first semiconductor material layer, wherein widths of the first opening are greater than widths of the first semiconductor material layer in the first horizontal direction and the second horizontal direction;
forming an insulating layer on a first sidewall of the first opening;
removing the first semiconductor material layer to form a second opening that exposes the first isolation layer;
removing the first isolation layer to extend the second opening; and
depositing a conductive material in the first opening and the second opening to form a first source/drain contact.

10. The method of claim 9, further comprising:
after removing the first semiconductor material layer, forming a carbon layer on the first isolation layer, wherein the insulating layer is formed after forming the carbon layer, and wherein the insulating layer is formed on the first sidewall of the first opening and a second sidewall of the second opening; and
after forming the insulating layer, removing the carbon layer.

11. The method of claim 10, further comprising:
conformally depositing a dielectric material layer in the first opening and the second opening; and
removing horizontal portions of the dielectric material layer to form a sidewall dielectric layer.

12. The method of claim 11,
wherein the sidewall dielectric layer comprises a first portion and a second portion,
wherein the first portion is formed on an upper portion of the insulating layer formed on the first sidewall of the first opening,
wherein the second portion is formed on a lower sidewall of the second sidewall of the second opening and below a lower portion of the insulating layer formed on an upper sidewall of the second sidewall of the second opening.

13. The method of claim 12, wherein a surface of the lower portion of the insulating layer is free of the sidewall dielectric layer.

14. The method of claim 9, further comprising:
before forming the insulating layer, introducing an inhibitor to the first semiconductor material layer through the first opening; and
after forming the insulating layer, removing the inhibitor from the first opening,
wherein the first semiconductor material layer is removed after removing the inhibitor.

15. The method of claim 9, further comprising:
removing the dummy gate structure and the first semiconductor layers to form a gate trench; and
forming a metal gate structure in the gate trench to wrap around each of the second semiconductor layers.

16. The method of claim 9, further comprising:
performing a planarization process on the backside of the substrate to expose the first hard mask layer, such that the second hard mask layer and portions of the insulating layer and the conductive material over the first hard mask layer are removed.

17. A semiconductor structure, comprising:
a substrate;
nanostructures below the substrate, wherein the nanostructures are spaced apart from each other in a vertical direction;
a gate structure wrapped around each of the nanostructures;
a first source/drain feature and a second source/drain feature, attached to opposite sides of the nanostructures in a first horizontal direction;
a hard mask layer over the substrate; and
a source/drain contact extending through the hard mask layer and the substrate and in contact with the first source/drain feature, wherein the source/drain contact comprises a first portion in contact with the first source/drain feature and a second portion on the first portion,
wherein widths of the second portion are greater than widths of the first portion in the first horizontal direction and a second horizontal direction, and wherein the second horizontal direction is perpendicular to the first horizontal direction,
wherein the second portion of the source/drain contact comprises a second conductive portion and a second insulating layer surrounding the second conductive portion,
wherein a portion of the substrate is vertically sandwiched between the second insulating layer and the nanostructures.

18. The semiconductor structure of claim 17, further comprising:
a sidewall dielectric layer surrounding a first conductive portion of the first portion of the source/drain contact, and surrounding the second conductive portion and between the second conductive portion and the second insulating layer.

19. The semiconductor structure of claim 18,
wherein the second insulating layer comprises a protrusion portion at a bottom of the second portion of the source/drain contact and a main portion over the protrusion portion, and
wherein a first portion of the sidewall dielectric layer between the protrusion portion of the second insulating layer and the second conductive portion is thinner than a second portion of the sidewall dielectric layer between the main portion of the second insulating layer and the second conductive portion.

20. The semiconductor structure of claim 17,
wherein the first portion of the source/drain contact comprises a first conductive portion and a first insulating layer surrounding an upper portion of the first conductive portion,
wherein the first portion of the source/drain contact comprises a first sidewall dielectric layer below the first insulating layer and surrounding a lower portion of the first conductive portion.
